(19) United States
(12) Patent Application Publication
(10) Pub. No.: US 2007/0089017 A1
(43) Pub. Date: Apr. 19, 2007

(54) Error correction decoder, method and computer program product for block serial pipelined layered decoding of structured low-density parity-check (LDPC) codes with reduced memory requirements

(75) Inventors: Jun Tang, Minneapolis, MN (US); Tejas Bhatt, Irving, TX (US); Vishwas Sundaramurthy, Irving, TX (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Nokia Corporation, Espoo (FI)

(21) Appl. No.: 11/272,919

(22) Filed: Nov. 14, 2005

Related U.S. Application Data
(63) Continuation-in-part of application No. 11/253,207, filed on Oct. 18, 2005.
(63) Continuation of application No. 11/273,552, filed on Nov. 14, 2005.

(51) Int. Cl. H03M 13/00

(52) U.S. Cl. 714/752

(57) ABSTRACT

An error correction decoder for block serial pipelined layered decoding of block codes includes a plurality of elements capable of processing, for at least one of a plurality of iterations of an iterative decoding technique, at least one layer of a parity check matrix. The elements include an iterative decoder element capable of calculating, for one or more iterations or one or more layers of the parity-check matrix processed during at least one iteration, a check-to-variable message based upon a first minimum magnitude and a second minimum magnitude of a plurality of variable-to-check messages for a previous iteration or layer, and a sign value associated with a plurality of variable-to-check messages for the previous iteration or layer. In this regard, the first and second minimum magnitudes and the sign value can be read from a check-to-variable message memory.

### CROSS-REFERENCE TO RELATED APPLICATIONS

The present application is a continuation of U.S. patent application Ser. No. ______, entitled: Error Correction Decoder, Method and Computer Program Product for Block Serial Pipelined Layered Decoding of structured Low-Density Parity-Check (LDPC) Codes, Including Calculating Check-To-Variable Messages, filed concurrently herewith, which is a continuation-in-part of U.S. patent application Ser. No. 11/253,207, entitled: Block Serial Pipelined Layered Decoding Architecture for Structured Low-Density Parity-Check (LDPC) Codes, filed Oct. 18, 2005, the contents of both of which are incorporated herein by reference in their entireties.

### FIELD

The present invention generally relates to error control and error correction encoding and decoding techniques for communication systems, and more particularly relates to block decoding techniques such as low-density parity-check (LDPC) decoding techniques.

### BACKGROUND

Low-density parity-check (LDPC) codes have recently been the subject of increased research interest for their enhanced performance on additive white Gaussian noise (AWGN) channels. As described by Shannon's Channel Coding Theorem, the best performance is achieved when using a code consisting of very long codewords. In practice, codeword size is limited in the interest of reducing complexity, buffering, and delays. LDPC codes are block codes, as opposed to trellis codes that are built on convolutional codes. LDPC codes constitute a large family of codes including turbo codes. Block codewords are generated by multiplying (modulo 2) binary information words with a binary matrix generator. LDPC codes use a parity-check matrix H, which is used for decoding. The term low density derives from the characteristic that the parity-check matrix has a very low density of non-zero values, making it a relatively low complexity decoder while retaining good error protection properties.

The parity-check matrix H measures (N−K)×N, wherein N represents the number of elements in a codeword and K represents the number of information elements in the codeword. The matrix H is also termed the LDPC mother code. For the specific example of a binary alphabet, N is the number of bits in the codeword and K is the number of information bits contained in the codeword for transmission over a wireless or a wired communication network or system. The number of information elements is therefore less than the number of codeword elements, so K<N. FIGS. 1a and 1b graphically describe an LDPC code. The parity-check matrix 10 of FIG. 1a is an example of a commonly used 512×4608 matrix, wherein each matrix column 12 corresponds to a codeword element (variable node of FIG. 1b) and each matrix row 14 corresponds to a parity-check equation (check node of FIG. 1b). If each column of the matrix H includes exactly the same number m of non-zero elements, and each row of the matrix H includes exactly the same number k of non-zero elements, the matrix represents what is termed a regular LDPC code. If the code allows for non-uniform counts of non-zero elements among the columns and/or rows, it is termed an irregular LDPC code.

Irregular LDPC codes have been shown to significantly outperform regular LDPC codes, which has generated renewed interest in this coding system since its inception decades ago. The bipartite graph of FIG. 1b illustrates that each codeword element (variable nodes 16) is connected only to parity-check equations (check nodes 18) and not directly to other codeword elements (and vice versa). Each connection, termed a variable edge 20 or a check edge 22 (each edge represented by a line in FIG. 1b), connects a variable node to a check node and represents a non-zero element in the parity-check matrix H. The number of variable edges connected to a particular variable node 16 is termed its degree, and the number of variable degrees 24 are shown corresponding to the number of variable edges emanating from each variable node. Similarly, the number of check edges connected to a particular check node is termed its degree, and the number of check degrees 26 are shown corresponding to the number of check edges 22 emanating from each check node. Since the degree (variable, check) represents non-zero elements of the matrix H, the bipartite graph of FIG. 1b represents an irregular LDPC code matrix. The following discussion is directed toward irregular LDPC codes since they are more complex and potentially more useful, but may also be applied to regular LDPC codes with normal skill in the art.

Even as the overall computational complexity in decoding regular and irregular LDPC codes can be lower than turbo codes, the memory requirements of an LDPC decoder can be quite high. In an effort to at least partially reduce the memory requirements of an LDPC decoder, various techniques for designing LDPC codes have been developed. And although such techniques are adequate in reducing the memory requirements of an LDPC decoder, such techniques may suffer from an undesirable amount of decoding latency, and/or limited throughput.

### SUMMARY

In view of the foregoing background, exemplary embodiments of the present invention provide an improved error correction decoder, method and computer program product for block serial pipelined layered decoding of block codes. Generally, and as explained below, exemplary embodiments of the present invention provide an architecture for an LDPC decoder that calculates check-to-variable messages in accordance with an improved min-sum approximation algorithm that reduces degradation that may be otherwise introduced into the decoder by the approximation. Exemplary embodiments of the present invention are also capable of reducing memory requirements of the decoder by storing values from which check-to-variable messages may be calculated, as opposed to storing check-to-variable messages themselves. In addition, exemplary embodiments of the present invention provide a reconfigurable permuter/de-permuter whereby cyclic shifts in data values may be accomplished by means of a permuting Benes network in response to control logic generated by a sorting Benes network.

Further, the decoder may be configured to pipeline operations of an iterative decoding algorithm. In this regard, the architecture of exemplary embodiments of the present invention may include a running sum memory and (duplicate) mirror memory to store accumulated log-likelihood values for iterations of an iterative decoding technique. Such an architecture may improve latency of the decoder by a factor of two or more, as compared to conventional LDPC decoder architectures. In addition, the architecture may include a processor configuration that further reduces latency in performing operations in accordance with a min-sum algorithm for approximating a sub-calculation of the iterative decoding technique or algorithm.

According to one aspect of the present invention, an error correction decoder is provided for block serial pipelined layered decoding of block codes. The decoder includes a plurality of elements capable of processing, for at least one of a plurality of iterations q=0, 1, . . . , Q of an iterative decoding technique, at least one layer l of a parity check matrix H. The elements include an iterative decoder element (or a plurality of such decoder elements) capable of calculating, for one or more iterations q or one or more layers of the parity-check matrix processed during at least one iteration, a check-to-variable message cᵢvⱼ^{[q]} upon a first minimum magnitude MIN and a second minimum magnitude MIN2 of a plurality of variable-to-check messages for a previous iteration or layer vⱼcᵢ^{[q-1]}, and a sign value S_{i,j} associated with a plurality of variable-to-check messages for the previous iteration or layer. In this regard, the first and second minimum magnitudes and the sign value can be read from a check-to-variable message memory. The iterative decoder element can be capable of calculating the check-to-variable message further based upon a third minimum magnitude of the plurality of variable-to-check messages for a previous iteration or layer. In such instances, the third minimum magnitude can also be read from the check-to-variable message memory.

More particularly, the parity-check matrix H can include a plurality of columns corresponding to a plurality of variable nodes vⱼ such that the plurality of variable-to-check messages vⱼcᵢ have indices j′ corresponding to respective variable nodes. In such instances, the indices can include a first index I1 corresponding to the variable-to-check message having the first minimum magnitudes. The iterative decoder element can therefore be capable of calculating the check-to-variable message further based upon the first index. In this regard, the iterative decoder element can be capable of selecting the first or second minimum value, as well as selecting a sign value from a plurality of sign values associated with the plurality of variable-to-check messages for the previous iteration or layer, based upon the first index I1. The decoder can further include a read interface capable of reading the selected magnitude and sign value from the check-to-variable message memory such that the iterative decoder element can be capable of calculating the check-to-variable message based upon the read magnitude and sign value.

The decoder can also include primary and mirror memories that are each capable of storing log-likelihood ratios (LLRs), L(tⱼ), for at least one of the iterations of the iterative decoding technique. In this regard, the iterative decoder element can be further capable of calculating, for at least one iteration or layer, a LLR adjustment ΔL(tⱼ)^{[q]} based upon the LLR for a previous iteration or layer L(tⱼ)^{[q-1]} and the check-to-variable message for the previous iteration or layer cᵢvⱼ^{[q-1]}. In such instances, the LLR for the previous iteration or layer can be read from the primary memory. The decoder can include a summation element capable of reading the LLR for the previous iteration or layer L(tⱼ)^{[q-1]} from the mirror memory, and calculating the LLR for the iteration or layer L(tⱼ)^{[q]} based upon the LLR adjustment ΔL(tⱼ)^{[q]} for the iteration or layer and the LLR for the previous iteration or layer L(tⱼ)^{[q-1]}.

The decoder can further include a permuter and/or de-permuter capable of permuting the LLR for the previous iteration or layer L(tⱼ)^{[q-1]}, or de-permuting at least a portion of the LLR for the iteration or layer (e.g., adjustment ΔL(tⱼ)^{[q]}. The permuter/de-permuter can include a permuting Benes network and a sorting Benes network. In this regard, the permuting Benes network can include a plurality of switches for permuting the LLR for the previous iteration or layer, or de-permuting the at least a portion of the LLR for the iteration or layer. Driving the permuting Benes network, the sorting Benes network can be capable of generating control logic for the switches of the permuting Benes network.

According to other aspects of the present invention, a network entity and a computer program product are provided for error correction decoding. Exemplary embodiments of the present invention therefore provide an improved network entity, method and computer program product. And as indicated above and explained in greater detail below, the network entity, method and computer program product of exemplary embodiments of the present invention may solve the problems identified by prior techniques and may provide additional advantages.

### BRIEF DESCRIPTION OF THE DRAWINGS

Having thus described the invention in general terms, reference will now be made to the accompanying drawings, which are not necessarily drawn to scale, and wherein:

FIG. 1a is a matrix of an exemplary low-density parity-check mother code, according to exemplary embodiments of the present invention;

FIG. 1b is a bipartite graph depicting connections between variable and check nodes, according to exemplary embodiments of the present invention;

FIG. 2 illustrates a schematic block diagram of a wireless communication system including a plurality of network entities, according to exemplary embodiments of the present invention;

FIG. 3 is a logical block diagram of a communication system according to exemplary embodiments of the present invention;

FIG. 4 is a graph illustrating performance of a modified min-sum algorithm, as well as comparable performance of original min-sum and log-map algorithms, in accordance with an exemplary embodiment of the present invention;

FIG. 5 is a schematic block diagram of an error correction decoder, in accordance with an exemplary embodiment of the present invention;

FIG. 6 is a control flow diagram of a number of elements of the error correction decoder of FIG. 5, in accordance with an exemplary embodiment of the present invention;

FIG. 7 is a timing diagram illustrating pipelining during operation of the decoder of FIG. 5, in accordance with an exemplary embodiment of the present invention;

FIG. 8 is a timing diagram illustrating pipelining during operation of an error correction decoder of another exemplary embodiment of the present invention;

FIG. 9 is a schematic block diagram of an error correction decoder, in accordance with another exemplary embodiment of the present invention, the timing diagram of which is shown in FIG. 8;

FIG. 10 is a control flow diagram of a number of elements of the error correction decoder of FIG. 9, in accordance with an exemplary embodiment of the present invention;

FIGS. 11 and 12 are functional block diagrams of one of an array of processors of an error correction decoder, in accordance with two exemplary embodiments of the present invention;

FIG. 13 is an S-input, S-output Benes network in accordance with an exemplary embodiment of the present invention;

FIGS. 14 and 15 are schematic block diagrams of a permuter (and de-permuter), in accordance with two exemplary embodiments of the present invention; and

FIGS. 16 and 17 are schematic block diagrams of Benes networks illustrating how input arrays of different sizes may be sorted using the same Benes network, in accordance with two exemplary embodiments of the present invention.

### DETAILED DESCRIPTION

The present invention now will be described more fully hereinafter with reference to the accompanying drawings, in which exemplary embodiments of the invention are shown. This invention may, however, be embodied in many different forms and should not be construed as limited to the exemplary embodiments set forth herein; rather, these exemplary embodiments are provided so that this disclosure will be thorough and complete, and will fully convey the scope of the invention to those skilled in the art. Like numbers refer to like elements throughout.

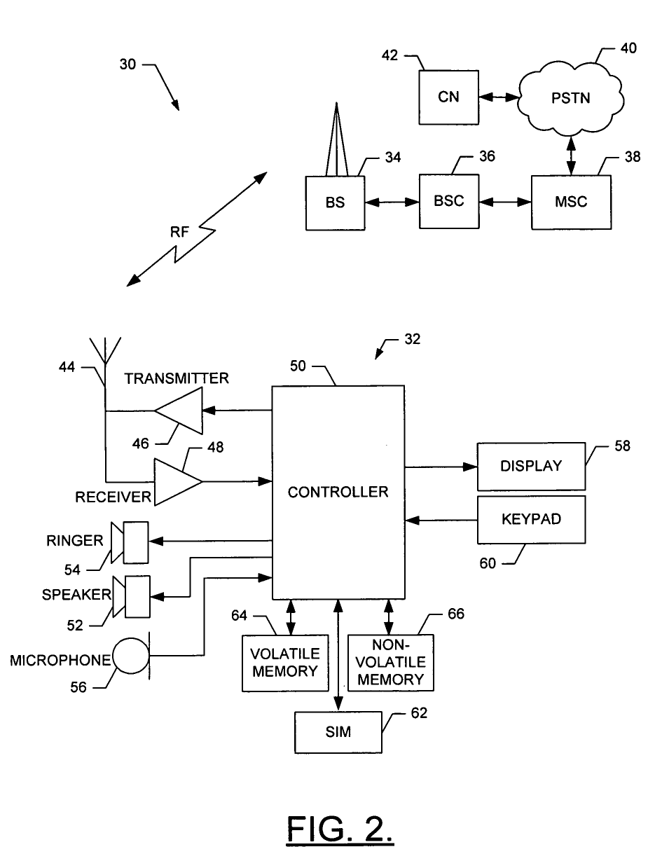

Referring to FIG. 2, an illustration of one type of wireless communications system 30 including a plurality of network entities, one of which comprises a terminal 32 that would benefit from the present invention is provided. As explained below, the terminal may comprise a mobile telephone. It should be understood, however, that such a mobile telephone is merely illustrative of one type of terminal that would benefit from the present invention and, therefore, should not be taken to limit the scope of the present invention. While several exemplary embodiments of the terminal are illustrated and will be hereinafter described for purposes of example, other types of terminals, such as portable digital assistants (PDAs), pagers, laptop computers and other types of voice and text communications systems, can readily employ the present invention. In addition, the system and method of the present invention will be primarily described in conjunction with mobile communications applications. It should be understood, however, that the system and method of the present invention can be utilized in conjunction with a variety of other applications, both in the mobile communications industries and outside of the mobile communications industries.

The communication system 30 provides for radio communication between two communication stations, such as a base station (BS) 34 and the terminal 32, by way of radio links formed therebetween. The terminal is configured to receive and transmit signals to communicate with a plurality of base stations, including the illustrated base station. The communication system can be configured to operate in accordance with one or more of a number of different types of spread-spectrum communication, or more particularly, in accordance with one or more of a number of different types of spread spectrum communication protocols. More particularly, the communication system can be configured to operate in accordance with any of a number of 1G, 2G, 2.5G and/or 3G communication protocols or the like. For example, the communication system may be configured to operate in accordance with 2G wireless communication protocols IS-95 (CDMA) and/or cdma2000. Also, for example, the communication system may be configured to operate in accordance with 3G wireless communication protocols such as Universal Mobile Telephone System (UMTS) employing Wideband Code Division Multiple Access (WCDMA) radio access technology. Further, for example, the communication system may be configured to operate in accordance with enhanced 3G wireless communication protocols such as 1X-EVDO (TIA/EIA/IS-856) and/or 1X-EVDV. It should be understood that operation of the exemplary embodiment of the present invention is similarly also possible in other types of radio, and other, communication systems. Therefore, while the following description may describe operation of an exemplary embodiment of the present invention with respect to the aforementioned wireless communication protocols, operation of an exemplary embodiment of the present invention can analogously be described with respect to any of various other types of wireless communication protocols, without departing from the spirit and scope of the present invention.

The base station 34 is coupled to a base station controller (BSC) 36. And the base station controller is, in turn, coupled to a mobile switching center (MSC) 38. The MSC is coupled to a network backbone, here a PSTN (public switched telephonic network) 40. In turn, a correspondent node (CN) 42 is coupled to the PSTN. A communication path is formable between the correspondent node and the terminal 32 by way of the PSTN, the MSC, the BSC and base station, and a radio link formed between the base station and the terminal. Thereby, the communications, of both voice data and non-voice data, are effectual between the CN and the terminal. In the illustrated, exemplary implementation, the base station defines a cell, and numerous cell sites are positioned at spaced-apart locations throughout a geographical area to define a plurality of cells within any of which the terminal is capable of radio communication with an associated base station in communication therewith.

The terminal 32 includes various means for performing one or more functions in accordance with exemplary embodiments of the present invention, including those more particularly shown and described herein. It should be understood, however, that the terminal may include alternative means for performing one or more like functions, without departing from the spirit and scope of the present invention. More particularly, for example, as shown in FIG. 2, in addition to one or more antennas 44, the terminal of one exemplary embodiment of the present invention can include a transmitter 26, receiver 48, and controller 50 or other processor that provides signals to and receives signals from the transmitter and receiver, respectively. These signals include signaling information in accordance with the communication protocol(s) of the wireless communication system, and also user speech and/or user generated data. In this regard, the terminal can be capable of communicating in accordance with one or more of a number of different wireless communication protocols, such as those indicated above. Although not shown, the terminal can also be capable of communicating in accordance with one or more wireline and/or wireless networking techniques. More particularly, for example, the terminal can be capable of communicating in accordance with local area network (LAN), metropolitan area network (MAN), and/or a wide area network (WAN) (e.g., Internet) wireline networking techniques. Additionally or alternatively, for example, the terminal can be capable of communicating in accordance with wireless networking techniques including wireless LAN (WLAN) techniques such as IEEE 802.11 (e.g., 802.11a, 802.11b, 802.11g, 802.11n, etc.), WiMAX techniques such as IEEE 802.16, and/or ultra wideband (UWB) techniques such as IEEE 802.15 or the like.

It is understood that the controller 50 includes the circuitry required for implementing the audio and logic functions of the terminal 32. For example, the controller may be comprised of a digital signal processor device, a microprocessor device, and/or various analog-to-digital converters, digital-to-analog converters, and other support circuits. The control and signal processing functions of the terminal are allocated between these devices according to their respective capabilities. The controller can additionally include an internal voice coder (VC), and may include an internal data modem (DM). Further, the controller may include the functionality to operate one or more client applications, which may be stored in memory (described below).

The terminal 32 can also include a user interface including a conventional earphone or speaker 52, a ringer 54, a microphone 56, a display 58, and a user input interface, all of which are coupled to the controller 38. The user input interface, which allows the terminal to receive data, can comprise any of a number of devices allowing the terminal to receive data, such as a keypad 60, a touch display (not shown) or other input device. In exemplary embodiments including a keypad, the keypad includes the conventional numeric (0-9) and related keys (#, *), and other keys used for operating the terminal. Although not shown, the terminal can include one or more means for sharing and/or obtaining data (not shown).

In addition, the terminal 32 can include memory, such as a subscriber identity module (SIM) 62, a removable user identity module (R-UIM) or the like, which typically stores information elements related to a mobile subscriber. In addition to the SIM, the terminal can include other removable and/or fixed memory. In this regard, the terminal can include volatile memory 64, such as volatile Random Access Memory (RAM) including a cache area for the temporary storage of data. The terminal can also include other non-volatile memory 66, which can be embedded and/or may be removable. The non-volatile memory can additionally or alternatively comprise an EEPROM, flash memory or the like. The memories can store any of a number of client applications, instructions, pieces of information, and data, used by the terminal to implement the functions of the terminal.

As described herein, the client application(s) may each comprise software operated by the respective entities. It should be understood, however, that any one or more of the client applications described herein can alternatively comprise firmware or hardware, without departing from the spirit and scope of the present invention. Generally, then, the network entities (e.g., terminal 32, BS 34, BSC 36, etc.) of exemplary embodiments of the present invention can include one or more logic elements for performing various functions of one or more client application(s). As will be appreciated, the logic elements can be embodied in any of a number of different manners. In this regard, the logic elements performing the functions of one or more client applications can be embodied in an integrated circuit assembly including one or more integrated circuits integral or otherwise in communication with a respective network entity or more particularly, for example, a processor or controller of the respective network entity. The design of integrated circuits is by and large a highly automated process. In this regard, complex and powerful software tools are available for converting a logic level design into a semiconductor circuit design ready to be etched and formed on a semiconductor substrate. These software tools, such as those provided by Avant! Corporation of Fremont, Calif. and Cadence Design, of San Jose, Calif., automatically route conductors and locate components on a semiconductor chip using well established rules of design as well as huge libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

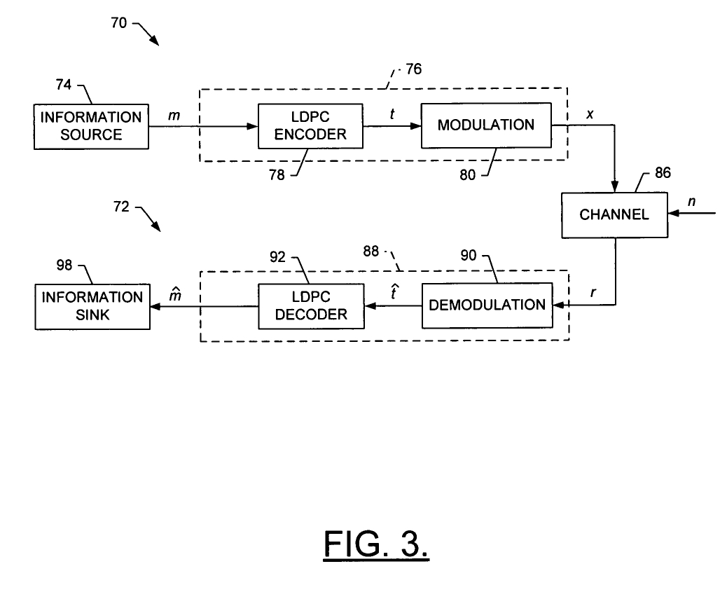

Reference is now made to FIG. 3, which illustrates a functional block diagram of the system 30 of FIG. 2 in accordance with one exemplary embodiment of the present invention. As shown, the system includes a transmitting entity 70 (e.g., BS 34) and a receiving entity 72 (e.g., terminal 32). As shown and described below, the system and method of exemplary embodiments of the present invention operate to decode structured irregular low-density parity-check (LDPC) codes. It should be understood, however, that the system and method of exemplary embodiments of the present invention may be equally applicable to decoding regular LDPC codes, without departing from the spirit and scope of the present invention. It should further be understood that the transmitting and receiving entities may be implemented into any of a number of different types of transmission systems that transmit coded or uncoded digital transmissions over a radio interface.

In the illustrated system, an information source 74 of the transmitting entity 70 can output a K-dimensional sequence of information bits m into a transmitter 76 that includes an LDPC encoder 78, modulation element 80 and memory 82, 84. The LDPC encoder is capable of encoding the sequence m into an N-dimensional codeword t by accessing a LDPC code in memory. The transmitting entity can thereafter transmit the codeword t to the receiving entity 72 over one or more channels 86. Before the codeword elements are transmitted over the channel(s), however, the codeword t including the respective elements can be broken up into sub-vectors and provided to the modulation element, which can modulate and up-convert the sub-vectors to a vector x of the sub-vectors. The vector x can then be transmitted over the channel(s).

As the vector x is transmitted over the channel(s) 86 (or by virtue of system hardware), additive white Gaussian noise (AWGN) n can be added thereto so that the vector r=x+n is received by the receiving entity 72 and input into a receiver 88 of the receiving entity. The receiver can include a demodulation element 90, a LDPC decoder 92 and memory for the same LDPC code used by the transmitter 76. The demodulation element can demodulate vector r, such as in a symbol-by-symbol manner, to thereby produce a hard-decision vector \hat{t} on the received information vector t. The demodulation element can also calculate probabilities of the decision being correct, and then output the hard-decision vector and probabilities to the LDPC decoder. Alternatively, the demodulation element may calculate a soft-decision vector on the received information vector, where the soft-decision vector includes the probabilities of the decision made. The LDPC decoder can then decode the received code block and output a decoded information vector \hat{m} to an information sink 98.

A. Structured LDPC Codes

As shown and explained herein, the LDPC code utilized by the LDPC encoder 78 and the LDPC decoder 92 for performing the respective functions can comprise a structured LDPC code. In this regard, the structured LDPC code can comprise a regular structured LDPC code where each column of parity-check matrix H including exactly the same number m of non-zero elements, and each row including exactly the same number k of non-zero elements. Alternatively, the structured LDPC code can comprise an irregular structured LDPC code where the parity-check matrix H allows for non-uniform counts of non-zero elements among the columns and/or rows. Accordingly, the LDPC code in memory 84, 96 can comprise such a regular or irregular structured LDPC code.

As will be appreciated, the parity-check matrix H of exemplary embodiments of the present invention can be comprised in any of a number of different manners. For example, the parity-check matrix H can comprise an expanded parity-check matrix including a number of sub-matrices, with matrix H being constructed based upon a set of permutation matrices P and/or null matrices (all-zeros matrices where every element is a zero). In this regard, consider a structured irregular rate one-third (i.e., R-⅓) LDPC code defined by the following partitioned parity-check matrix of dimension 12×18:

$$H = [ \begin{matrix}0 & 0 & 1 & 0 & 0 & 0 & 0 & 0 & 0 & 0 & 0 & 1 & 0 & 0 & 0 & 0 & 0 & 0 \\ 1 & 0 & 0 & 0 & 0 & 0 & 0 & 0 & 0 & 1 & 0 & 0 & 0 & 0 & 0 & 0 & 0 & 0 \\ 0 & 1 & 0 & 0 & 0 & 0 & 0 & 0 & 0 & 0 & 1 & 0 & 0 & 0 & 0 & 0 & 0 & 0 \\ 1 & 0 & 0 & 0 & 1 & 0 & 0 & 0 & 0 & 1 & 0 & 0 & 0 & 1 & 0 & 0 & 0 & 0 \\ 0 & 1 & 0 & 0 & 0 & 1 & 0 & 0 & 0 & 0 & 1 & 0 & 0 & 0 & 1 & 0 & 0 & 0 \\ 0 & 0 & 1 & 1 & 0 & 0 & 0 & 0 & 0 & 0 & 0 & 1 & 1 & 0 & 0 & 0 & 0 & 0 \\ 0 & 0 & 0 & 1 & 0 & 0 & 1 & 0 & 0 & 0 & 0 & 0 & 0 & 0 & 0 & 0 & 0 & 1 \\ 0 & 0 & 0 & 0 & 1 & 0 & 0 & 1 & 0 & 0 & 0 & 0 & 0 & 0 & 0 & 1 & 0 & 0 \\ 0 & 0 & 0 & 0 & 0 & 1 & 0 & 0 & 1 & 0 & 0 & 0 & 0 & 0 & 0 & 0 & 1 & 0 \\ 0 & 0 & 0 & 0 & 0 & 0 & 1 & 0 & 0 & 0 & 0 & 0 & 0 & 1 & 0 & 0 & 0 & 1 \\ 0 & 0 & 0 & 0 & 0 & 0 & 0 & 1 & 0 & 0 & 0 & 0 & 0 & 0 & 1 & 1 & 0 & 0 \\ 0 & 0 & 0 & 0 & 0 & 0 & 0 & 0 & 1 & 0 & 0 & 0 & 1 & 0 & 0 & 0 & 1 & 0\end{matrix} ]$$

Generally, the permutation matrices, from which the parity-check matrix H can be constructed, each comprise an identity matrix with one or more permuted columns or rows. The permutation matrices can be constructed or otherwise selected in any of a number of different manners. One permutation matrix, P_{SPREAD}¹, capable of being selected in accordance with exemplary embodiments of the present invention can comprise the following single circular shift permutation matrix:

$${P}_{SPREAD}^{1} = [ \begin{matrix}0 & 1 & 0 & 0 & 0 \\ 0 & 0 & 1 & 0 & 0 \\ 0 & 0 & 0 & 1 & 0 \\ 0 & 0 & 0 & 0 & 1 \\ 1 & 0 & 0 & 0 & 0\end{matrix} ]$$

In such instances, cyclically shifted permutation matrices facilitate representing the LDPC code in a compact fashion, where each sub-matrix of the parity-check matrix H can be identified by a shift. It should be understood, however, that other non-circular or even randomly or pseudo-randomly shifted permutation matrices can alternatively be selected in accordance with exemplary embodiments of the present invention. For example, P_{SPREAD}¹ can comprise the following alternate non-circular shift permutation matrix:

$${P}_{SPREAD}^{1} = [ \begin{matrix}0 & 0 & 0 & 0 & 1 \\ 0 & 0 & 1 & 0 & 0 \\ 0 & 1 & 0 & 0 & 0 \\ 1 & 0 & 0 & 0 & 0 \\ 0 & 0 & 0 & 1 & 0\end{matrix} ]$$

For more information on one exemplary method for constructing irregularly structured LDPC codes, see U.S. patent application Ser. No. 11/174,335, entitled: Irregularly Structured, Low Density Parity Check Codes, filed Jul. 1, 2005, the content of which is hereby incorporated by reference.
B. Layered Belief Propagation Decoding Algorithm

Irrespective of the type and construction of the LDPC code (parity-check matrix H), the LDPC decoder 92 of exemplary embodiments of the present invention is capable of decoding a received code block in accordance with a layered belief propagation technique. Before describing such a layered belief propagation technique, a belief propagation decoding technique will be described, with the layered belief propagation technique thereafter being described with reference to the belief propagation technique.

1. Belief Propagation Decoding Algorithm

Consider a message vector m encoded with an LCPC code of dimension N×K, where the LDPC code is defined by a parity-check matrix H of dimension (N−K)×N. Also, let t represent the LDPC codeword, and tⱼ represent the jth transmitted code bit. In such an instance, the log-likelihood-ratio (LLR) of tⱼ can be defined as follows:

$$L ( {t}_{j} ) = log ( \frac{Pr ( {t}_{j} = 0 )}{Pr ( {t}_{j} = 1 )} )$$

Further, let rⱼ represent the received value and λⱼ represent the input channel value to the LDPC decoder 92 for the bit tⱼ, which can be computed by the demodulation element 90.

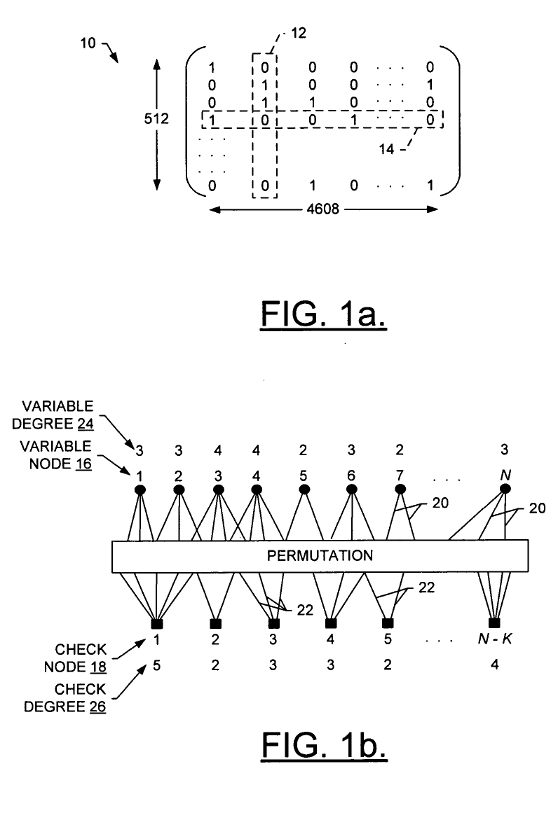

In accordance with a belief propagation decoding algorithm, the LDPC decoder 92 can iteratively calculate extrinsic messages from each check 18 to the participating bits 16 (check-node to variable-node message). In addition, the LDPC decoder can iteratively calculate extrinsic messages from each bit to the checks in which the bit participates (variable-node to check-node message). The calculated messages can then be passed on the edges 20, 22 of an associated bipartite graph (see FIG. 1b). In the preceding, it should be noted that the terms bit-node and variable-node may be used interchangeably. Also, the calculated extrinsic messages can be referred to as check-to-variable or variable-to-check messages as appropriate.

More particularly, in accordance with an iterative belief propagation decoding algorithm, the LDPC decoder 92 can be initialized at iteration index q=0. As or after initializing the decoder, the LLR of bit-node j at the end of iteration q (i.e., L(tⱼ)^{[q]}) can be calculated for q=0, such as in the following manner:
L(tⱼ)^{[0]}=λⱼ, j=0, 1, 2, . . . , N−1
In addition to calculating the LLR of bit-node j, extrinsic messages from check node i to variable node j at iteration q (i.e., cᵢvⱼ^{[q]}), and from variable node j to check node i at iteration q (i.e., vⱼcᵢ^{[q]}), can be calculated for q=0, where i and j represent the check-node index and bit-node index, respectively. Written notationally, the extrinsic messages can be calculated as follows:
cᵢvⱼ^{[0]}=0, ∀jεRᵢ, i=0, 1, 2, . . . , K−1
vⱼcᵢ^{[0]}=λⱼ, ∀iεCⱼ, j=0, 1, 2, . . . , N−1
In the preceding, Rᵢ represents the set of positions of columns having 1's in the ith row, and Cⱼ represents the set of positions of the rows having 1's in the jth column, both of which can be written notationally as follows:
Rᵢ={j|H_{i,j}=1}∀i,j
Cⱼ={i|H_{i,j}=1}∀i,j

After initializing the decoder 92 and calculating the LLR and extrinsic messages for q=0, the decoder can perform iterative decoding for iterations q=1, 2, 3, . . . , Q, iterative decoding including performing a horizontal operation, a vertical operation, a soft LLR output operation, a hard-decision operation and a syndrome calculation. The decoder can perform each operation/calculation for each iteration. For fixed iteration decoding, however, the decoder can perform the horizontal and vertical operations for each iteration, and then further perform the soft LLR output operation, hard-decision operation and syndrome calculation for the last iteration, q=Q.

The decoder 92 can perform the horizontal operation by calculating a check-to-variable message for each parity check node. Written notationally, for example, the horizontal operation can be performed in accordance with the following nested loop:
For i=0, 1, 2, . . . , K−1:
For j=Rᵢ[0], Rᵢ[1], Rᵢ[2], . . . , Rᵢ[ρᵢ−1]:

$$M ( {c}_{i} {v}_{j}^{[ q ]} ) = {ψ}^{- 1} [ {\sum }_{{j}^{′} ∈ R [ i ] \backslash j} ψ ( \vert {v}_{{j}^{′}} {c}_{i}^{[ q - 1 ]} \vert ) ]$$

$$S ( {c}_{i} {v}_{j}^{[ q ]} ) = {( - 1 )}^{{ρ}_{i}} {\prod }_{{j}^{′} ∈ R [ i ] \backslash \{ j \}} sign ( {v}_{{j}^{′}} {c}_{i}^{[ q - 1 ]} )$$

$${c}_{i} {v}_{j}^{[ q ]} = - S ( {c}_{i} {v}_{j}^{[ q ]} ) \times M ( {c}_{i} {v}_{j}^{[ q ]} )$$

In the preceding nested loop, M and S represent the magnitude and sign of check-to-variable message cᵢvⱼ^{[q]}, respectively. Also, the variable ρᵢ represents the number of elements in Rᵢ, and ψ⁻¹(x) can be calculated as follows:

$${ψ}^{- 1} ( x ) = ψ ( x ) = - \frac{1}{2} log ( tanh ( \frac{x}{2} ) )$$

Irrespective of exactly how the decoder 92 performs the horizontal operation, the decoder can perform the vertical operation by calculating a variable-to-check message for each variable node. More particularly, for example, the vertical operation can be performed in accordance with the following nested loop:
For j=0, 1, 2, . . . , N−1:
For i=Cⱼ[0], Cⱼ[1], Cⱼ[2], . . . , Cⱼ[υⱼ−1]:

$${v}_{j} {c}_{i}^{[ q ]} = {λ}_{j} + {\sum }_{{i}^{′} ∈ C [ j ] \backslash i} {c}_{{i}^{′}} {v}_{j}^{[ q ]}$$

In the preceding, similar to ρᵢ with respect to Rᵢ, υⱼ represents the number of elements in Cⱼ.

The decoder 92 can perform the soft LLR output operation by calculating a soft LLR for each bit tⱼ, such as in accordance with the following nested loop:
For j=0, 1, 2, . . . , N−1:
For i=0, 1, 2, . . . , vⱼ−1, iεC[j]:

$${L ( {t}_{j} )}^{[ q ]} = {λ}_{j} + {\sum }_{i ∈ C [ j ]} {c}_{i} {v}_{j}^{[ q ]}$$

The decoder 92 can perform the hard-decision operation by calculating a hard-decision code bit \hat{t}ⱼ for bit-nodes j=0, 1, 2, . . . , N−1, such as in the following manner:
For j=0, 1, 2, . . . , N−1:
   If L(tⱼ)^{[q]}>0, \hat{t}ⱼ=1, else \hat{t}ⱼ=0

Further, during the iterative decoding, the decoder 92 can calculate a syndrome s based upon the LDPC codeword t and the parity-check matrix H, such as in the following manner:
s=\hat{t}H^{T}
where, as used herein, superscript T notationally represents a matrix transpose. The decoder can then repeat the above iterative decoding operations/calculations for each iteration, that is until q>Q, or until s=0.

2. Layered Belief Propagation Decoding Algorithm

The number of iterations q required under the belief propagation algorithm can be reduced by employing the layered belief propagation algorithm. The layered belief propagation, described in this section, can be efficiently implemented for irregular structured partitioned codes. In this regard, consider the previously-given structured irregular LDPC code:

$$H = [ \begin{matrix}0 & 0 & 1 & 0 & 0 & 0 & 0 & 0 & 0 & 0 & 0 & 1 & 0 & 0 & 0 & 0 & 0 & 0 \\ 1 & 0 & 0 & 0 & 0 & 0 & 0 & 0 & 0 & 1 & 0 & 0 & 0 & 0 & 0 & 0 & 0 & 0 \\ 0 & 1 & 0 & 0 & 0 & 0 & 0 & 0 & 0 & 0 & 1 & 0 & 0 & 0 & 0 & 0 & 0 & 0 \\ 1 & 0 & 0 & 0 & 1 & 0 & 0 & 0 & 0 & 1 & 0 & 0 & 0 & 1 & 0 & 0 & 0 & 0 \\ 0 & 1 & 0 & 0 & 0 & 1 & 0 & 0 & 0 & 0 & 1 & 0 & 0 & 0 & 1 & 0 & 0 & 0 \\ 0 & 0 & 1 & 1 & 0 & 0 & 0 & 0 & 0 & 0 & 0 & 1 & 1 & 0 & 0 & 0 & 0 & 0 \\ 0 & 0 & 0 & 1 & 0 & 0 & 1 & 0 & 0 & 0 & 0 & 0 & 0 & 0 & 0 & 0 & 0 & 1 \\ 0 & 0 & 0 & 0 & 1 & 0 & 0 & 1 & 0 & 0 & 0 & 0 & 0 & 0 & 0 & 1 & 0 & 0 \\ 0 & 0 & 0 & 0 & 0 & 1 & 0 & 0 & 1 & 0 & 0 & 0 & 0 & 0 & 0 & 0 & 1 & 0 \\ 0 & 0 & 0 & 0 & 0 & 0 & 1 & 0 & 0 & 0 & 0 & 0 & 0 & 1 & 0 & 0 & 0 & 1 \\ 0 & 0 & 0 & 0 & 0 & 0 & 0 & 1 & 0 & 0 & 0 & 0 & 0 & 0 & 1 & 1 & 0 & 0 \\ 0 & 0 & 0 & 0 & 0 & 0 & 0 & 0 & 1 & 0 & 0 & 0 & 1 & 0 & 0 & 0 & 1 & 0\end{matrix} ]$$

As shown, the preceding parity-check matrix H can be partitioned into smaller non-overlapping sub-matrices of dimension 3×3, where each sub-matrix can be referred to as a permuted identity matrix. Generally, then, a LDPC code of dimension N×K can be defined by a parity check matrix partitioned into sub-matrices of dimension S₁×S₂. In such instances, it should be noted that each row of a partition can include an equal number of 1's, as can each column of a partition.

With reference to the above LDPC code, then, a set of non-overlapping rows can form a layer or a block-row (sometimes referred to as a “supercode”), where the parity check matrix may include L=K/S₁, partitioned layers (i.e., supercodes), and C=N/S₂ block columns. In this regard, a layer can include a group of non-overlapping checks in parity-check matrix, all of which can be decoded in parallel without exchanging any information. In accordance with a layered belief propagation decoding algorithm, the extrinsic messages can be updated after each layer is processed. Thus, layered belief propagation can be summarized as computing new check-to-variable messages for each layer of each of a number of iterations, and updating the variable-to-check messages using updated check-to-variable messages. For a final iteration, then, a hard-decision and syndrome vector can be computed.

More particularly, in accordance with a layered belief propagation decoding algorithm, the LDPC decoder 92 can be initialized at iteration index q=0, such as in the same manner as in the belief propagation algorithm including calculating the LLR of bit-node j for q=0 (i.e., L(tⱼ)^{[0]}) and the check-to-variable message for q=0 (i.e., cᵢvⱼ^{[0]}). The decoder 92 can then perform iterative decoding for iterations q=1, 2, 3, . . . , Q, iterative decoding including performing a horizontal operation, a soft LLR update operation and a syndrome calculation. The decoder can perform each operation/calculation for each iteration. For fixed iteration decoding, however, the decoder can perform the horizontal and soft LLR update operations for each iteration, and then further perform the hard-decision operation and syndrome calculation for the last iteration, q=Q.

The decoder 92 can perform the horizontal and soft LLR update operations by calculating a check-to-variable message for each parity check node, and updating the soft LLR output for each bit tⱼ, for each layer. Written notationally, for example, the horizontal and vertical operations can be performed in accordance with the following nested loop:

For l=0, 1, 2, . . . , L−1:
For s=0, 1, 2, . . . , S₁−1:
   i=l×S₁+s
For j=Rᵢ[0], Rᵢ[1], Rᵢ[2], . . . , Rᵢ[ρₗ−1]:
Horizontal Operation:

$$M ( {c}_{i} {v}_{j}^{[ q ]} ) = {ψ}^{- 1} [ {\sum }_{{j}^{′} ∈ R [ i ] \backslash \{ j \}} ψ ( \vert {L ( {t}_{{j}^{′}} )}^{[ q - 1 ]} {c}_{i} {v}_{{j}^{′}}^{[ q - 1 ]} \vert ) ]$$

$$S ( {c}_{i} {v}_{j}^{[ q ]} ) = {( - 1 )}^{{ρ}_{i}} {\prod }_{{j}^{′} ∈ R [ i ] \backslash \{ j \}} sign ( {L ( {t}_{{j}^{′}} )}^{[ q - 1 ]} - {c}_{i} {v}_{{j}^{′}}^{[ q - 1 ]} )$$

$${c}_{i} {v}_{j}^{[ q ]} = - S ( {c}_{i} {v}_{j}^{[ q ]} ) \times M ( {c}_{i} {v}_{j}^{[ q ]} )$$
Soft LLR Update:
   L(tⱼ)^{[q]}=L(tⱼ)^{[q-1]}+cᵢvⱼ^{[q]}−cᵢvⱼ^{[q-1]}

Similar to in the belief propagation algorithm, the decoder 92 implementing the layered belief propagation algorithm can perform the hard-decision operation by calculating a hard-decision code bit \hat{t}ⱼ for bit-nodes j=0, 1, 2, . . . , N−1, such as in the following manner:
For j=0, 1, 2, . . . , N−1:
   If L(tⱼ)^{[q]}>0, \hat{t}ⱼ=1, else \hat{t}ⱼ=0

In addition, the decoder 92 can calculate a syndrome s based upon the hard-decision LDPC codeword \hat{t} and the parity-check matrix H, such as in the following manner:
s=\hat{t}H^{T}
The decoder can then repeat the above iterative decoding operations/calculations for each iteration, that is until q>Q, or until s=0.

Even though tan-h (i.e., ψ(x)) may be one of the more common descriptions of belief propagation and layered belief propagation in the log-domain, those skilled in the arts will recognize that several other operations (e.g. log-MAP) and/or approximations (e.g. look-up table, min-sum, min-sum with correction term) can be used to implement (ψ(x)). A reduced complexity min-sum approach or algorithm may also be used, where such a min-sum approach may simplify complex log-domain operations at the expense of a reduction in performance. In accordance with such an algorithm, the M(cᵢvⱼ^{[q]}) calculation of the horizontal operation can be approximated as follows:
M(cᵢvⱼ^{[q]})≈min(|L(x_{j′})^{[q-1]}−cᵢv_{j′}^{[q-1]}|, j′=1, 2, . . . , ρⱼ−1, j′≠j)

To further reduce the complexity of the min-sum algorithm, exemplary embodiments of the present invention are capable of determining the above minimum value based upon a first minimum value and a next, second minimum value. More particularly, the horizontal operation can be performed by first calculating a minimum value in accordance with the following:
MIN=min(|L(x_{j′})^{[q-1]}−cᵢv_{j′}^{[q-1]}|, j′=1, 2, . . . , ρⱼ−1)
For example, if the index j′ of the minimum value is set to I1, then the next minimum value can be calculated from among the remaining values (i.e., excluding the minimum value MIN), such as in accordance with the following:
MIN2=min(|L(x_{j′})^{[q-1]}−cᵢv_{j′}^{[q-1]}|, j′=1, 2, . . . , ρⱼ−1, j′≠I1)
Then, after calculating S(cᵢvⱼ^{[q]}), the horizontal operation can conclude by calculating the check-to-variable message based upon the minimum and next minimum values, such as in accordance with the following:

If j=I1,
cᵢvⱼ^{[q]}=−S(cᵢvⱼ^{[q]})×MIN2,

else,
cᵢvⱼ^{[q]}=−S(cᵢvⱼ^{[q]})×MIN
During implementation of the min-sum algorithm, the soft LLR update and hard decision-operations can be performed as before.

As will be appreciated, the reduced complexity of the min-sum algorithm may come with the price of performance degradation (e.g., 0.3−0.5 dB) compared with log-map or tan-h algorithms. To improve the performance of the min-sum algorithm, then, exemplary embodiments of the present invention may account for such degradation by approximating error introduced in approximating the magnitude M(cᵢvⱼ^{[q]}). In this regard, consider that the error term in the min-sum algorithm (with two variable nodes may be represented as follows):
ψ⁻¹(ψ(x)+ψ(y))=min(x, y)+error
∴error=ψ⁻¹(ψ(x)+ψ(y))−min(x, y)
∴error=ln[1+e^{-|x+y|}]−ln[1+e^{-|x-y|}]≈−ln[1+e^{-|x-y|}]
From the preceding, then, the min-sum algorithm including the error term can be rewritten as follows:
ψ⁻¹(ψ(x)+ψ(y))≈min(x, y)−ln[1+e^{-|x-y|}]

If so desired, the error term in the above expression can be approximated by a function of x and y, as follows:

$$ln [ 1 + {ⅇ}^{- \vert x - y \vert} ] \approx F ( x , y ) ≡ max ( \frac{5}{8} - \frac{- \vert x - y \vert}{4} , 0 )$$

which can be implemented with simple hardware circuit. In accordance with such a modified min-sum algorithm, then, the magnitude M(cᵢvⱼ^{[q]}) can be calculated as follows:

$$M ( {c}_{i} {v}_{j}^{[ q ]} ) = \{ \begin{matrix}MIN 2 - F ( MIN 3 , MIN 2 ) , & {j}^{′} = I 1 \\ MIN - F ( MIN 3 , MIN ) , & {j}^{′} = I 2 \\ MIN - F ( MIN 2 , MIN ) - F ( MIN 3 , MIN ) , & {j}^{′} \neq I 1 , I 2\end{matrix}$$

In the preceding equation, I2 represents the index j′ of the next minimum value, and MIN3 represents a following, third minimum value. In this regard, similar to MIN2, MIN3 can be calculated as follows:
MIN3=min(|L(x_{j′})^{[q-1]}−cᵢv_{j′}^{[q-1]}|, j′=1, 2, . . . , ρⱼ−1, j′≠I1, I2)

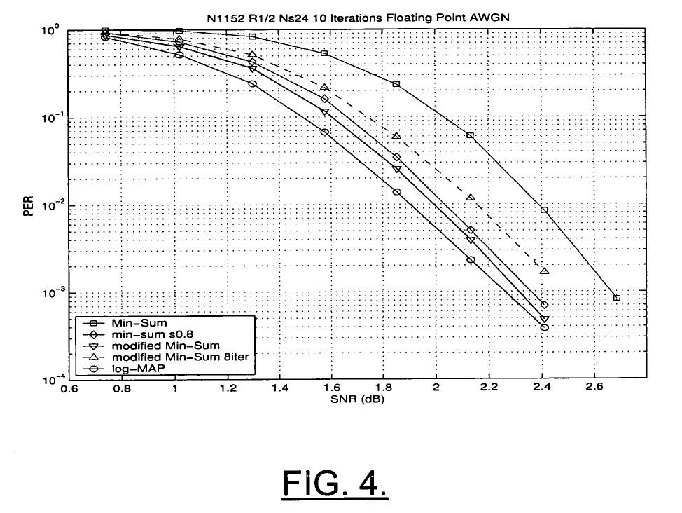

FIG. 4 is a graph illustrating performance of the modified min-sum algorithm, as well as comparable performance of the original min-sum and log-map algorithms. As shown, performance of modified-min-sum is greater than that of the original min-sum algorithm, and approaches that of the log-map algorithm. As the modified-min-sum can achieve increased performance with a fewer number of iterations, the throughput enabled in the decoder can be further enhanced.

C. Pipelined Layered Decoder Architecture

As explained above, the layered belief propagation algorithm can improve performance by passing updated extrinsic messages between the layers within a decoding iteration. In a structured parity-check matrix H as defined above, each block row can define one layer. The more the overlap between two layers, then, the more the information passed between the layers. However, decoders for implementing the layered belief propagation algorithm can suffer from dependency between the layers. Each layer can be processed in a serial manner, with information being updated at the end of each layer. Such dependence can create a bottleneck in achieving high throughput.

One manner by which higher throughput can be achieved is to simultaneously process multiple layers. In such instances, information can be passed between groups of layers, as opposed to being passed between each layer. To analyze this approach, conventional min-sum can be viewed as clubbing all the layers in one group, while layered belief propagation can be viewed as having one layer (block row) in each group of layers. It can be shown that the performance gain may gradually improve when reducing the number of layers grouped together in one group. Moreover, it can be shown that in some cases it may be beneficial to group consecutive block-rows in one fixed layer, while in others the non-consecutive block rows are grouped in one fixed layer, thereby resulting in performance close to that achievable by the actual layered decoding algorithm. This is because different block rows have different overlap in a parity check matrix. Thus, in parallel layer processing, scheduling block rows with better connection in different groups improves the performance. The best scheduling can therefore depend on the code structure. Such scheduling may also be utilized to obtain faster convergence in fading channels.

Parallel block row processing such as that explained above, however, can require more decoder resources. In this regard, the decoder resources for check and variable node processing can linearly scale with the number of parallel layers. The memory partitioning and synchronization at the end of processing of a group of layer can be rather complex. As explained below, however, grouping layers as indicated above can be leveraged to employ a pipelined decoder architecture.

In accordance with exemplary embodiments of the present invention, then, the LDPC decoder 92 can have a pipelined layered architecture for implementing a layered belief propagation decoding technique or algorithm. Before describing the pipelined layered decoder architecture of exemplary embodiments of the present invention, other decoder architectures for implementing the belief propagation and layered belief propagation decoding techniques will be described, the pipelined layered decoder architectures thereafter being described with reference to those architectures.

1. Belief Propagation Decoder Architecture

A number of decoder architectures have been developed for implementing the belief propagation algorithm. To implement the belief propagation algorithm, computational complexity can be minimized using the min-sum approach or a look-up table for a tan-h implementation. Such approaches can reduce the decoder calculations to simple add, compare, sign and memory access operations. A joint coder/decoder design has also been considered where decoder architectures exploit the structure of the parity-check matrix H to obtain better parallelism, reduce required memory and improve throughput.

The various belief propagation decoder architectures that have been developed can generally be described as serial, fully-parallel and semi-parallel architectures. In this regard, while serial architectures require the least amount of decoder resources, such architectures typically have limited throughput. Fully-parallel architectures, on the other hand, may yield a high throughput gain, but such architectures may require more decoder resources and a fully connected message-passing network. LDPC decoding, while in theory offers a lot of inherent parallelism, requires a fully connected network that presents a complex interconnect problem even with structured codes. Fully-parallel architectures may be very code-specific and may not be reconfigurable or flexible. Semi-parallel architectures, on the other hand, may provide a trade-off between throughput, decoder resources and power consumption.

Another bottleneck in implementing a belief propagation decoding algorithm may be memory management. In this regard, since the message-passing feature of belief propagation can be accomplished via memory accesses, a lack of structure in the parity-check matrix H can lead to access conflicts, and adversely affect the throughput. Structured codes, however, may be designed to improve memory management in the LDPC decoder 92.

In its simplest form, a decoder implementing a belief propagation algorithm may require

$${\sum }_{k = 1}^{K} {ρ}_{k}$$

memory locations to store check-to-variable messages,

$${\sum }_{n = 1}^{N} {υ}_{n}$$

memory locations to store variable-to-check messages, and N memory locations to store the final log-likelihood-ratios (LLRs) of the coded bits.

2. Layered Belief Propagation Decoder Architecture

Generally, as extrinsic messages can be updated during each sub-iteration, only one memory location may be required by a decoder to maintain the LLR and accumulated variable-to-check messages. As such, in comparison toga decoder implementing a belief propagation algorithm, a decoder implementing a layered belief propagation algorithm may only require N memory locations, instead of

$${\sum }_{n = 1}^{N} {υ}_{n}$$

memory locations, to store variable-to-check messages.

In one layered belief propagation decoder architecture, accumulated variable-to-check messages may not be stored, but rather computed at every layer. That is,

$$M ( {c}_{i} {v}_{j}^{[ q ]} ) = {ψ}^{- 1} [ {\sum }_{{j}^{′} ∈ R [ i ] \backslash j} ψ ( \vert {λ}_{{j}^{′}} + {\sum }_{{i}^{′} ∈ C [ j ] \backslash i} {c}_{{i}^{′}} {v}_{{j}^{′}}^{[ q - 1 ]} \vert ) ]$$

Such a decoder architecture can lead to reduction in memory at the expense of the extra computations at each layer, with the check-to-variable for the current layer being over-written for the next layer. Also, such a decoder architecture may be particularly applicable to instances where there are fewer layers and the maximum variable node degree is comparatively small (e.g., 3, 4, etc.). For a code with more layers, however, such an architecture, may exhibit higher latency or require greater decoder resources, as discussed in greater detail below.

3. Pipelined Layered Belief Propagation Decoder Architecture

Different decoder architectures for decoding irregular structured LDPC codes will now be evaluated. For purposes of illustration, the following discussion assumes LDPC codes constructed using a partitioned technique with a shifted identity matrix as a sub- matrix. In this regard, assume a N×K LDPC code defined by a parity-check matrix partitioned into sub-matrices of dimension S×S. In such an instance, the parity-check matrix can include L=K/S partitioned layers (i.e., supercodes), and C=N/S block columns. Also, let ρₗ represent the number of non-zero sub-matrices in layer l, and υ_{c} represent the number of non-zero sub-matrices in block column c.

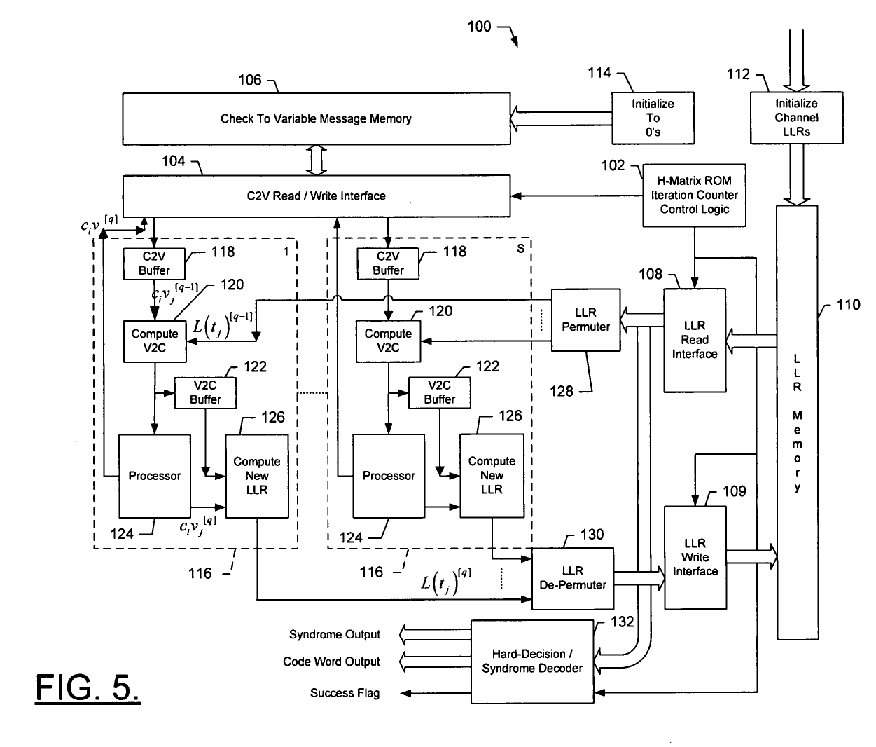

First, consider a block-by-block architecture where a LDPC decoder 100 can process each sub-matrix in a serial fashion, as shown in the schematic block diagram of FIG. 5. As shown, the decoder includes a parity-check matrix element 102 for storing the parity-check matrix H, and for providing address decoding and iteration/layer counting operations. In this regard, the parity-check matrix can communicate, via a check-to-variable (“C2V”) read/write interface 104, with a check-to-variable memory 106 for storing check-to-variable messages. Similarly, the parity-check matrix can communicate, via a LLR read interface 108 and a LLR write interface 109, with a bit-node LLR memory 110 for storing LLR and accumulated variable-to-check messages.

The decoder 100 can include a channel LLR initialization element 112 for initializing the bit-node LLR memory 110 with input soft bits at iteration index q=0 (i.e., L(tⱼ)^{[0]}=λⱼ), as well as an iteration initialization element 114 for initializing the check-to-variable messages at iteration index q=0 (i.e., Cᵢvⱼ^{[0]}). The decoder can also include a number of iterative decoder elements 116 (e.g., S iterative decoder elements for sub-matrices of dimension S×S) for performing the horizontal and soft LLR update operations for iterations q=1, 2, 3, . . . , Q. To perform the horizontal and soft LLR update operations, each iterative decoder element can include a check-to-variable buffer 118, a variable-to-check element 120, a variable-to-check buffer 122, a processor 124 and an LLR element 126.

For each iteration q, the variable-to-check element 120 is capable of receiving the LLR for iteration q−1, (i.e., L(tⱼ)^{[q-1]}) from a LLR permuter 128, which is capable of permuting the LLRs for processing by the iterative decoder elements 116, as more particularly explained below. In addition, the variable-to-check element is capable of receiving the check-to-variable message for iteration q−1 (i.e., cᵢvⱼ^{[q-1]}) and a LLR from the check-to-variable buffer 118. The variable-to-check element can then output, to the variable-to-check buffer 122 and processor 124, the variable-to-check message (i.e., L(tⱼ)^{[q-1]}−cᵢvⱼ^{[q-1]}) for iteration q−1. The processor is capable of performing the horizontal operation of the iterative decoding by calculating the check-to-variable message for iteration q (i.e., cᵢvⱼ^{[q]}) based upon the variable-to-check message for iteration q−1. The LLR element 126 is then capable of receiving the check-to-variable message from the processor, as well as the variable-to-check message from the variable-to-check buffer, and performing the soft LLR update by calculating the LLR for iteration q (i.e., L(tⱼ)^{[q]}). The calculated soft LLR for iteration q can be provided to a LLR de-permuter 130, which is capable of de-permuting the current iteration LLR, and outputting the current iteration LLR to the bit-node LLR memory 110 via the LLR write interface 109. For the last iteration Q, then, the soft LLR (i.e., L(tⱼ)^{[Q]},j=0, 1, 2, . . . , N−1) can be read from the bit-node LLR memory to a hard-decision/syndrome decoder element 132, which can calculate hard-decision code bits \hat{t}ⱼ based thereon. In addition, the hard-decision/syndrome decoder element can calculate a syndrome s based upon the hard-decision LDPC codeword \hat{t} and the parity-check matrix H.

In the illustrated architecture, each sub-matrix in a parity-check matrix H can be treated as a block, with processing of each row within a block being implemented in parallel. Thus, the decoder 100 can include S iterative decoder elements 116 in parallel, with each processor 124 of each iterative decoder element being capable of processing one of the parity-check equations in parallel. In this regard, the iterative decoder element can calculate the variable-to-check messages, and store those messages in a running-sum memory 110 that, as indicated above, can be initialized with input soft-bits. Thus, the illustrated decoder architecture may only require one memory 110 of length N for storing both input LLR and accumulated variable-to-check messages, thereby reducing the memory otherwise required by a belief propagation decoder by a factor of

$$N / {\sum }_{j = 1}^{N} {υ}_{j} .$$

As also shown, the check-to-variable memory 106 can be organized in a vertical dimension of the parity-check matrix H, and check-to-variable messages can be stored for each parity-check equation. Thus, a total of

$${\sum }_{l = 1}^{L} ( S \times {ρ}_{l} )$$

soft-words may be required to store check-to-variable messages.

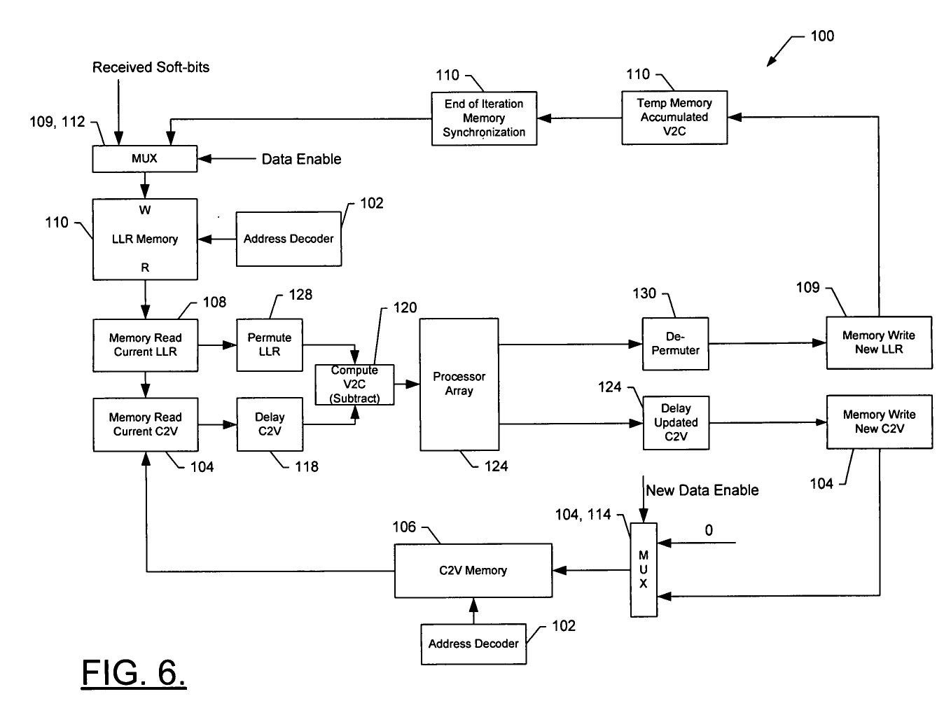

A control flow diagram of a number of elements of the decoder 100 implementing the iterative decoding of layered belief propagation is shown in FIG. 6. From the illustrated control flow diagram, it can be shown that the belief propagation algorithm can be segmented in different stages, each stage being dependent on the previous stage. In the illustrated decoder 100, pipelining can be enforced between different stages to reduce latency in performing the iterative decoding in accordance with the layered belief propagation. In this regard, the new check-to-variable messages and updated bit-node LLR accumulation (including variable-to-check messages) can be made available when the last block of data is read and processed. At the end of completion of the processing of one layer, then, the data can be written back to memory 106, 110 in a serial manner.

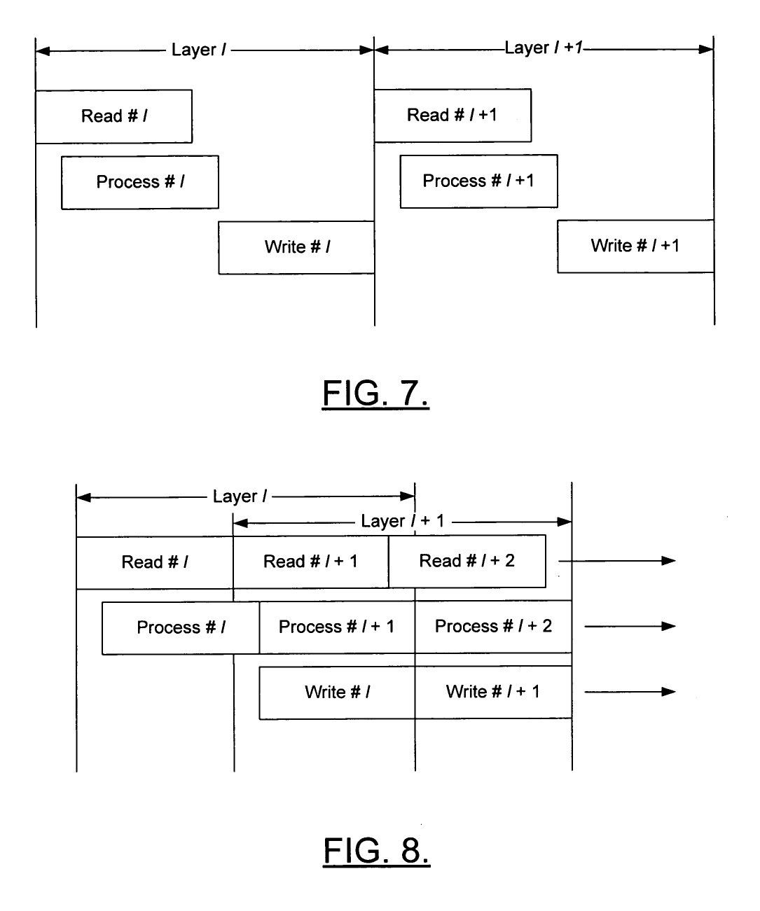

For illustrative purposes to evaluate performance of the decoder architecture of FIG. 5, presume the decoder 100 can process each iterative decoding stage in one clock cycle (see FIG. 6). Undesirably, the decoder may begin to read and process a new layer only after the extrinsic messages are updated for the current layer (read, processed and written), as shown in the timing diagram of FIG. 7. In this regard, if the architecture implementing the control flow diagram of FIG. 6 has P pipeline stages, and assuming that layer l includes ρₗ blocks (that is each parity-check equation in the layer has ρₗ variable-node connections), then processing of a layer can consume P+ρₗ+ρₗ−1=2ρₗ+P−1 (P-pipeline-stages+ρₗ non-zero sub-matrix read+ρₗ non-zero sub-matrix write) clock cycles. Thus, the number of required clock cycles for each iteration can be computed as follows:

$$Num Clock Cycles Per Iteration = {\sum }_{l = 1}^{L} ( 2 {ρ}_{l} + P - 1 )$$

As will be appreciated, the latency associated with layered mode belief propagation can be undesirably high, especially for an LDPC code with multiple layers. It should be noted, however, that for the same performance, conventional belief propagation can require more than two times the iterations required by the layered belief propagation. As such, the latency of conventional belief propagation can be much more than that of layered decoding.

To further reduce the latency of layered decoding, exemplary embodiments of the present invention exploit the results of parallel layer processing to enforce pipelining across layers over the entire parity-check matrix H. In this regard, the LDPC decoder of exemplary embodiments of the present invention is capable of beginning to process the next layer as soon as the last sub-matrix of the current layer is read and processed (reading the next layer as soon as the last-sub matrix of the current layer is read), as shown in the timing diagram of FIG. 8. Thus, the decoder of exemplary embodiments of the present invention is capable of overlapping processing of the next layer in parallel, thereby avoiding the latency in the final memory write stage at the end of each layer (i.e., latency in memory writing the new LLR and check-to-variable messages).

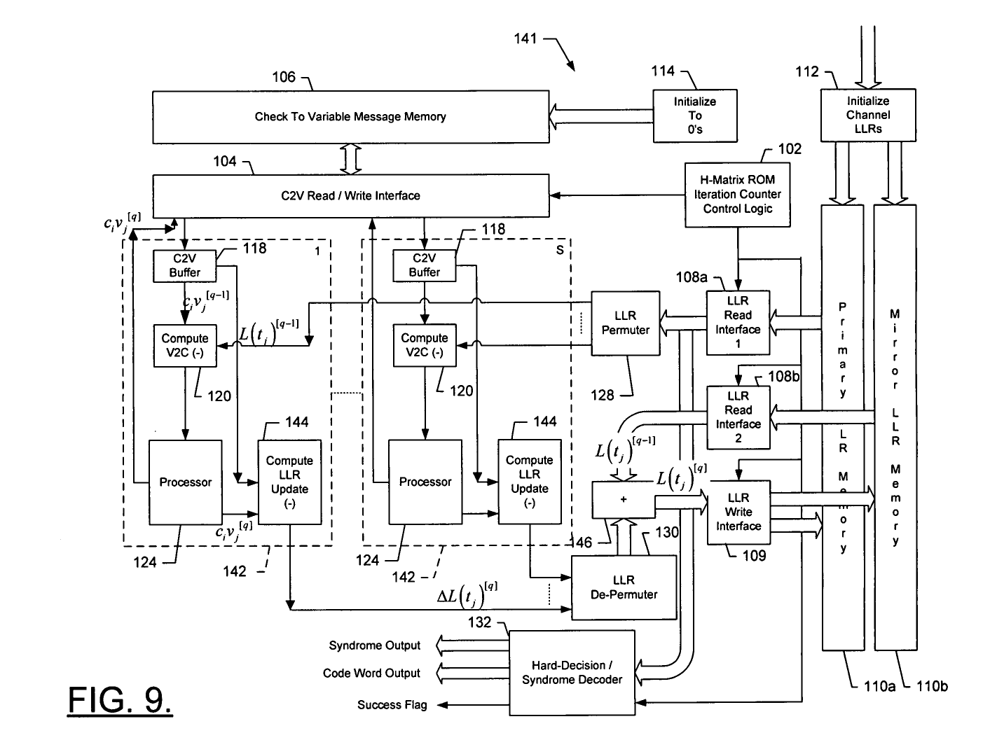

Reference is now made to the control flow diagram of FIG. 9, which illustrates a functional block diagram of a LDPC decoder 141 in accordance with exemplary embodiments of the present invention. To implement pipelining in accordance with exemplary embodiments of the present invention, instead of calculating an updated running sum and writing the running sum back to memory 110, the decoder is capable of calculating a bit-node (LLR) update (i.e., ΔL(tⱼ)^{[q]}=cᵢvⱼ^{[q-1]}) and updating the running sum with the calculated updates (i.e., ΔL(tⱼ)^{[q]}=ΔL(tⱼ)^{[q-1]}+ΔL(tⱼ)^{[q]}). In this regard, for bit node updates, the decoder is capable of reading an old LLR (i.e., L(tⱼ)^{[q-1}]), but writing back an updated LLR (i.e., ΔL(tⱼ)^{[q]}).

More particularly, similar to the LDPC decoder 100 of FIG. 5 (and FIG. 6), the LDPC decoder 141 of FIG. 9 can include a parity-check matrix element 102 for storing the parity-check matrix H, and for providing address decoding and iteration/layer counting operations. In this regard, the parity-check matrix can communicate, via a check-to-variable (“C2V”) read/write interface 104, with a check-to-variable memory 106 for storing check-to-variable messages. Similarly, the parity-check matrix can communicate, via a first LLR read interface 108a and a LLR write interface 109, with a primary bit-node LLR memory 110a for storing LLR and accumulated variable-to-check messages. In contrast to decoder 100 of FIG. 5, however, the decoder 141 of FIG. 9 can further include a second LLR read interface 108b for communicating with a mirror bit-node LLR memory 110b, with the LLR write interface also being capable of writing LLR and accumulated variable-to-check messages to the mirror bit-node LLR memory. In this regard, although the decoder 141 is shown as including first and second read interfaces, it should be understood that the functions of both can be implemented by a single read interface without departing from the spirit and scope of the present invention.

Also similar to the decoder 100 of FIG. 5, the decoder 141 of FIG. 9 can include a channel LLR initialization element 112 for initializing the bit-node LLR memories 110a and 110b with input soft bits at iteration index q=0 (i.e., L(tⱼ)^{[0]}=λⱼ), as well as an iteration initialization element 114 for initializing the check-to-variable messages at iteration index q=0 (i.e., cᵢvⱼ^{[0]}). The decoder can also include a number of iterative decoder elements 142 (for sub-matrices of dimension S×S) for performing the horizontal and soft LLR update operations for iterations q=1, 2, 3, . . . , Q. To perform the horizontal and soft LLR update operations, each iterative decoder element can include a check-to-variable buffer 118, a variable-to-check element 120 and a processor 124. Instead of a variable-to-check buffer 122 and an LLR element 126, as in the iterative decoder elements 116 of the decoder 100 of FIG. 5, however, the iterative decoder elements 142 of the decoder 141 of FIG. 9 includes an LLR update element 144.

As before, for each iteration q, the variable-to-check element 120 is capable of receiving the LLR for iteration q−1, (i.e., L(tⱼ)^{[q-1]}) from a LLR permuter 128, which is capable of permuting the LLRs for processing by the iterative decoder elements 142, as more particularly explained below. In addition, the variable-to-check element is capable of receiving the check-to-variable message for iteration q−1(i.e., cᵢvⱼ^{[q-1]}) and a LLR from the check-to-variable buffer 118, which is also capable of outputting the check-to-variable message for iteration q−1 to the LLR update element 144. The variable-to-check element can then output, to the processor 124, the variable-to-check message (i.e., L(tⱼ)^{[q-1]}−cᵢvⱼ^{[q-1]}) for iteration q−1. The processor is capable of performing the horizontal operation of the iterative decoding by calculating the check-to-variable message for iteration q (i.e., cᵢvⱼ^{[q]}) based upon the variable-to-check message for iteration q−1. The LLR update element 144 is capable of receiving the check-to-variable message from the processor, as well as the check-to-variable message for iteration q−1 from the check-to-variable buffer. The LLR update element can then perform a portion of the soft LLR update by calculating a bit-node (LLR) adjustment for iteration q (i.e., ΔL(tⱼ)^{[q]}=cᵢvⱼ^{[q]}−cᵢvⱼ^{[q-1]}). The calculated LLR adjustment for iteration q can be provided to a LLR de-permuter 130, which is capable of de-permuting the current iteration LLR adjustment, and outputting the current iteration LLR adjustment to a summation element 146. The summation element can also receive, from the mirror bit-node LLR memory 110b via the second LLR read interface 108b, the bit-node LLR for the previous iteration (i.e., L(tⱼ)^{[q-1]}).

The summation element 146 can complete the soft LLR update by summing the previous iteration bit-node LLR with the current iteration LLR adjustment (i.e., L(tⱼ)^{[q]}=L(tⱼ)^{[q-1]}+ΔL(tⱼ)^{[q]}), thereby updating the running sum with the calculated update. The current iteration bit-node LLR can then be written to the primary and mirror bit-node LLR memories 110a, 110b via the LLR write interface 109. Similar to before, for the last iteration Q, the soft LLR (i.e., L(tⱼ)^{[Q]}, j=0, 1, 2, . . . , N−1) can be read from the primary bit-node LLR memory to a hard-decision/syndrome decoder element 132, which can calculate hard-decision code bits \hat{t}ⱼ based thereon. In addition, the hard-decision/syndrome decoder element can calculate a syndrome s based upon the hard-decision LDPC codeword \hat{t} and the parity-check matrix H.

In the exemplary embodiment shown in FIG. 9, the decoder 141 includes a mirror LLR memory 110b because such LLR memory modules 110 may have only two ports, such as one read and one write, to access the data. As shown, then, two read and a write processes may simultaneously occur during an instruction cycle. If registers are used to store the bit node LLRs, then a single register bank, with three I/O ports, may alternatively be used. But such a register bank may not be suitable for hardware implementation of the decoder 141 as the required complexity to address the register bank may be prohibitively high.

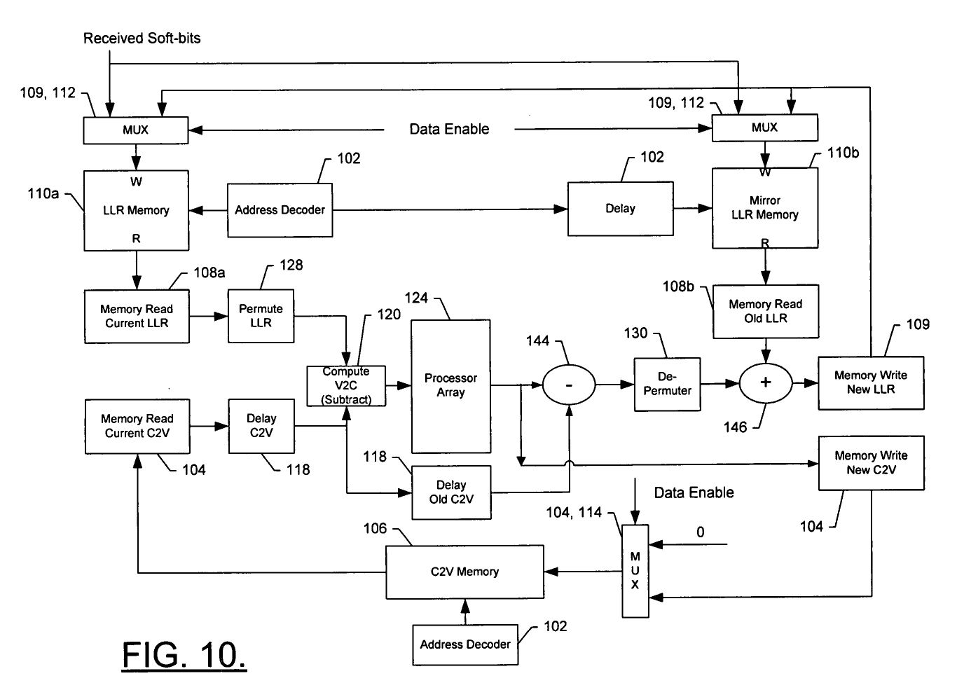

A control flow diagram of a number of elements of the decoder 141 implementation is shown in FIG. 10. As with the control flow diagram of FIG. 6, it can be shown that the belief propagation algorithm can be segmented in different stages. Again, for illustrative purposes to evaluate performance of the decoder architecture of FIG. 10, presume that layer l includes ρₗ blocks (that is each parity-check equation in the layer has ρₗ variable node connections), and that the pipeline has \tilde{P} stages. In such an instance, the number of clock cycles per iteration can be calculated as follows:

$$Num Clock Cycles Per Iteration = ( {\sum }_{l = 1}^{L} {ρ}_{l} ) + \tilde{P} - 1$$

For various LDPC codes, then, each layer can have check-node degrees that are within a unit distance of one another (i.e., difference between max check-node degree and min check-node degree is one). This allows efficient layout and usage of the processors 124. Also, the decoder 141 can be configured such that the pipeline can only be enforced if processing time in each layer is equal. A pseudo-computation cycle, then, can be inserted in order to enforce the pipeline. If it is assumed that each layer has ρ sub-matrices, then, neglecting differences in pipeline stages, the improvement in latency over the architecture of FIG. 5 can be calculated as follows:

$$\begin{matrix}Latency Improvement Per Iteration = \begin{matrix}( L \times ( 2 \times ρ + P - 1 ) ) - \\ ( L \times ρ + \tilde{P} - 1 )\end{matrix} \\ = L \times ( ρ - 1 ) + ( L \times P - \tilde{P} ) + 1\end{matrix}$$

$$Latency Improvement Per Iteration = \begin{matrix}L \times ( ρ - 1 ) + P \times \\ ( L - 1 ) ( ∵ P \approx \tilde{P} )\end{matrix}$$

D. Processor, Permuter/De-Permuter and Memory Configurations in Decoder Architecture

As will be appreciated, the processors 124, permuter 128, de-permuter 130 and memory 106 of the decoder architecture of exemplary embodiments of the present invention can be organized or otherwise configured in any of a number of different manners, such as in the manners explained below.

1. Processor Configuration

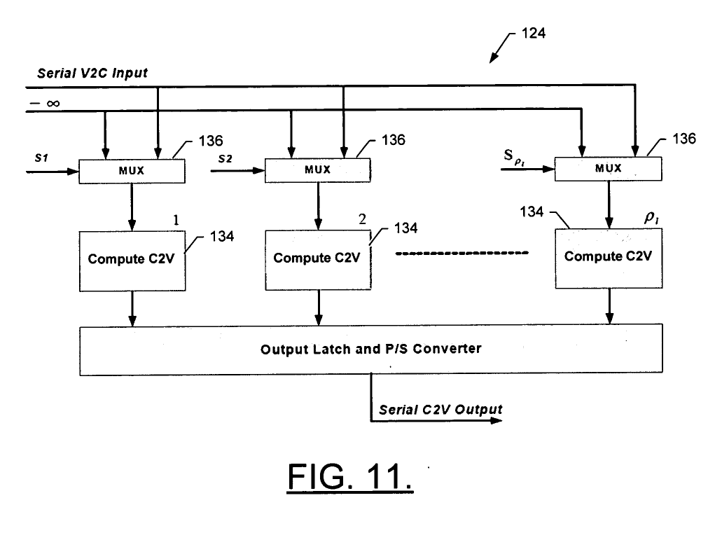

As will be appreciated, the processors 124 of the decoder architecture of exemplary embodiments of the present invention can be organized or otherwise configured in any of a number of different manners. The processors 124 of the iterative decoder elements 116, 142 of the LDPC decoder 100 can be configured in a number of different manners. In one exemplary hardware or software implementation, the processors 124 can be implemented using adders, look-up tables and sign manipulation elements. A reduced complexity min-sum implementation employs comparators and sign manipulation elements. In accordance with one configuration, for example, ρₗ comparator and sign manipulation elements 134 that compute the extrinsic check-to-variable messages cᵢvⱼ can be arranged in parallel for the parity check, as shown in FIG. 11. In such an arrangement, the variable-to-check messages (inputs) can be routed to the processors. Multiplexers 136 associated with the comparator and sign manipulation elements can be capable of excluding the variable-to-check message from the node that is being processed, and capable of implementing so-called extrinsic message calculation. Thus for a total of ρₗ inputs, each processor can calculate the extrinsic message between ρₗ−1 values.

In the configuration of FIG. 11, the check-to-variable messages can be calculated in parallel such that the check-to-variable messages can all be available as soon as the final input is processed. Further, the number of processors that are implemented in parallel can be set equal to ρₘₐₓ=max(ρ₁, ρ₂, . . . , ρ_{L}) Further, a total of ρₗ×(ρₗ−1) comparison operations can be carried out to calculate ρₗ extrinsic messages. It should be noted, however, that only about ρₗ clock cycles may be required to calculate the extrinsic messages as the check-node processors are arranged in parallel.

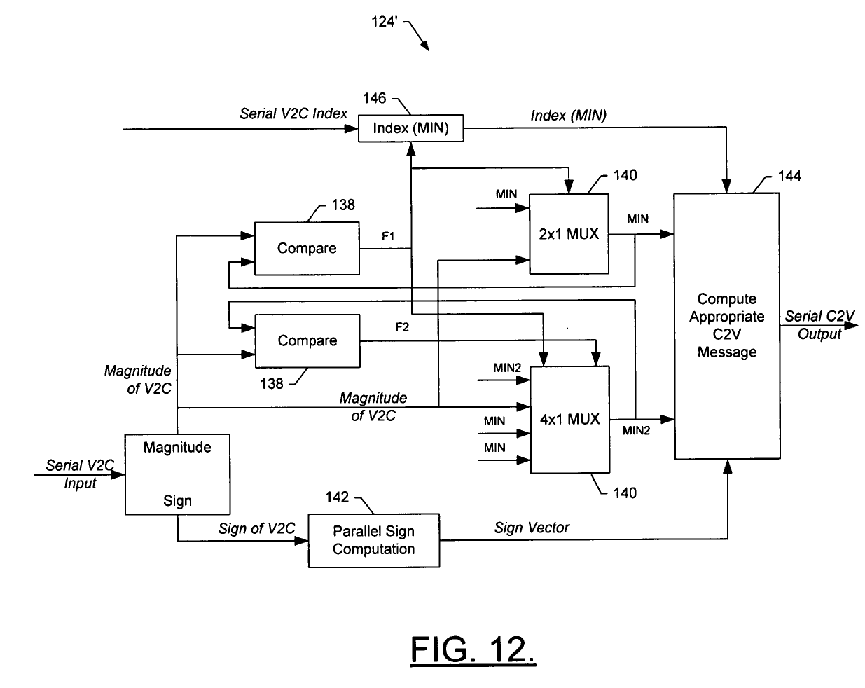

In another embodiment, as shown in FIG. 12, the processors 124′ can be configured for a reduced calculation implementation of the min-sum algorithm, reducing the number of calculations from ρₗ×(ρₗ−1) to 2×ρₗ. In accordance with such a reduced calculation implementation of the min-sum algorithm, the problem can be reduced to finding a minimum and a next minimum of the ρₗ values. In this regard, finding the minimum and next minimum can be implemented by compare elements 138 as two-level comparisons of current values of MIN and MIN2 with the serial variable-to-check messages (L(x_{j′})^{[q-1]}−cᵢv_{j′}^{[q-1]}) for j′=1, 2, . . . , ρⱼ−1 (i.e., “Input”), where MIN and MIN2 can be initialized to INF (e.g., the largest value of the fixed point precision). The compare elements can then output values F1 and F2 based upon the comparisons, such as in the following manner: value F1=1 if Input<MIN, else F1=0; and value F2=1 if Input<MIN2, else F2=0.

The output values F1 and F2 can then be fed into multiplexers 140 for updating the MIN and MIN2 values, such as in accordance with the following truth table (table I):

TRUTH TABLE

| F1 | F2 | MIN | MIN2 | Remark |
|---|---|---|---|---|
| 1 | — | Input | MIN | New MIN and MIN2 |
| 0 | 1 | MIN | Input | New MIN2, MIN Remains |
| 0 | 0 | MIN | MIN2 | Same MIN, MIN2 |

where “--” represents a “don't care” condition (although as shown, if F1=1, then F2=1). As will be appreciated, a similar two-level computational logic can be implemented with tan-h or log-map algorithms. In such instances, however, extra logic may be required to track the index of the minimum value in order to pass the correct check-to-variable message. Corresponding sign operation can be implemented as sign accumulation and subtraction element 142 (implemented, e.g., with a one-bit X-OR Boolean logic element). The current MIN and MIN2 values, along with the output of the sign operation (i.e., S(cᵢvⱼ[q]) can then be provided to a check-to-variable element 144 along with the index I1 of the current minimum value MIN from an index element 146. The check-to-variable element can then calculate the check-to-variable message cᵢvⱼ[q] based upon the index I1 and one of the MIN or MIN2 values, such as in accordance with the min-sum algorithm.

2. Permuter/De-Permuter Configuration

Similar to the processors 124, the permuter 128 and de-permuter 130 of the decoder architecture of exemplary embodiments of the present invention can be organized or otherwise configured in any of a number of different manners. The description below provides one such configuration for the permuter of exemplary embodiments of the present invention. It should be understood, however, that the configuration may equally apply to the de-permuter, without departing from the spirit and scope of the present invention.

In one exemplary embodiment, the permuter 128 (and de-permuter 130) can be implemented using multiplexers. To support any cyclic shift for a permutation matrix of size S, however, a total of S multiplexers of size S×1 may be required, thereby resulting in an overall complexity of O(S²). In another, lower-complex implementation, the permuter can include smaller, multi-stage multiplexers, thereby reducing the complexity to O(S log₂ S). Such low-complexity implementations, however, may be limited in the number of supported values of S, easily supporting S=Sₘₐₓ, Sₘₐₓ/2, . . . , 1, but oftentimes requiring complex control logic and pre-permutation logic for the other values of S. Further, efficient implementations can be easily derived for a single permutation matrix of size S, but such implementations may not be re-usable for implementing a cyclic shift of any permutation matrix of sizes 1, 2, . . . , S.

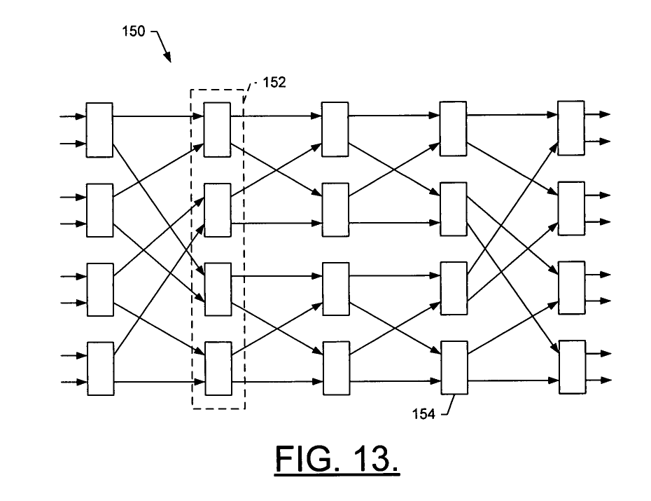

The permuter 128 (and de-permuter 130) of one exemplary embodiment can be implemented using Benes networks. Benes networks are known for being optimal non-blocking input-to-output routers. As shown in FIG. 13, an S-input, S-output (e.g., S=8) Benes network 150 generally comprises a switching network with 2 log₂(S)−1 stages 152, with each stage having S/2 switches 154. Each switch operates to route first and second inputs to first and second outputs based on the control state of the switch, typically either directly passing the inputs to the outputs (first and second inputs to first and second outputs, respectively) or exchanging the inputs and outputs (first and second inputs to second and first outputs, respectively). The control states (pass or exchange), then, can depend on the required permutation of the input (e.g., different cyclic shifts).

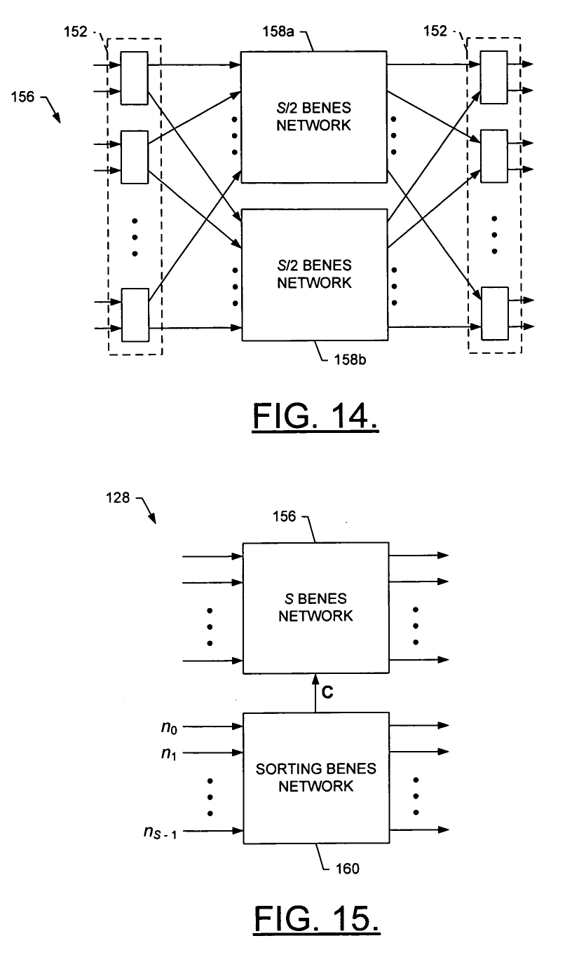

As shown in FIGS. 14 and 15, in accordance with one exemplary embodiment of the present invention, the permuter 128 (and de-permuter 130) can include an S×S permuting Benes network 156 formed from two S/2×S/2 Benes networks 158a, 158b with two additional stages 152. In addition, the permuter includes a sorting Benes network 160 that generates control logic for the switches 154 of the two S/2×S/2 Benes networks 158a, 158b to perform the desired permutation. In this regard, the sorting Benes network can receive known cyclically-shifted input integer array n₀, n₁, . . . , nₛ₋₁ (0≦nᵢ<S and nᵢ≠nⱼ, if i≠j), and route the input to an output, switch control matrix C in a way that yields an ordered sequence at the output. The switch control matrix can then be passed to the permuting Benes network 156 to incorporate the actual permutation of appropriate decoder messages. Due to mirror symmetry, in order to generate control logic for a cyclic shift of P performed on data of size S (P<S), the input to sorting Benes network can comprise the sequence [0, 1, . . . , S−1] shifted cyclically by an amount S−P. In such instances, the cyclic shift can be generated in a number of different manners, such as by means of a counter. An S×S Benes network and sorting Benes network can be used to cyclically permute any input of dimensions [1, 2, . . . , S]. Further, by partitioning the inputs, the Benes network can support any input dimension N(>S).

Assume that the permuter 128 receives an input array x₀, x₁, . . . , x_{S-1}, [Gentlemen—Should this be S or S−1 (the final report indicated S)?] and that the desired output is a cyclic shifted version of the of the input array, with a shift s<S. That is, assume that the desired output of the permuter is as follows:
yᵢ=x_{mod(s+i, S)}
For example, with an eight element input array (i.e., S=8), the possible cyclic shifts are listed in Table II. If each element xᵢ is assigned a unique integer ranging from 0 to S−1 at the input, by sorting the integers through the Benes network, it can be possible to achieve the desired cyclic shift operation through the same Benes network (and with the same switch control matrix C). For instance, consider an eight element input array, x₀, . . . , x₇ and a desired shift of s=3. In such an instance, the desired output array can comprise x₃, . . . , x₇, x₀, x₁, x₂. Table III illustrates how a sorting Benes network 160 can be used to achieve cyclic shifts of an input array with appropriate integer assignments to the elements in the array. In this regard, the assignment (mapping) can be represented as follows:
nᵢ=mod(i+S−s, S), i=0, 1, . . . , S−1

where nᵢ is the integer assigned to input element xᵢ for desired shift s.

TABLE II

| Input | x₀ | x₁ | x₂ | x₃ | x₄ | x₅ | x₆ | x₇ |
|---|---|---|---|---|---|---|---|---|
| s = 0 | x₀ | x₁ | x₂ | x₃ | x₄ | x₅ | x₆ | x₇ |
| s = 1 | x₁ | x₂ | x₃ | x₄ | x₅ | x₆ | x₇ | x₀ |
| s = 2 | x₂ | x₃ | x₄ | x₅ | x₆ | x₇ | x₀ | x₁ |
| s = 3 | x₃ | x₄ | x₅ | x₆ | x₇ | x₀ | x₁ | x₂ |
| s = 4 | x₄ | x₅ | x₆ | x₇ | x₀ | x₁ | x₂ | x₃ |
| s = 5 | x₅ | x₆ | x₇ | x₀ | x₁ | x₂ | x₃ | x₄ |
| s = 6 | x₆ | x₇ | x₀ | x₁ | x₂ | x₃ | x₄ | x₅ |
| s = 7 | x₇ | x₀ | x₁ | x₂ | x₃ | x₄ | x₅ | x₆ |

TABLE III

| Input | x₀ | x₁ | x₂ | x₃ | x₄ | x₅ | x₆ | x₇ |
|---|---|---|---|---|---|---|---|---|
| Integer Assigned | 5 | 6 | 7 | 0 | 1 | 2 | 3 | 4 |
| Integer After Sorting Benes | 0 | 1 | 2 | 3 | 4 | 5 | 6 | 7 |
| Network | | | | | | | | |
| Corresponding Output with Same | x₃ | x₄ | x₅ | x₆ | x₇ | x₀ | x₁ | x₂ |
| Benes Network | | | | | | | | |

After illustrating that the integer sorting Benes network can be used for cyclic shifting, a switch control matrix C can be calculated by the sorting Benes network 160 in accordance with a Benes network sorting (BNS) algorithm (BNSA). In the BNS algorithm, for simplicity, assume that S is a power of two, although it should be understood that S need not be a power of two. Now, presume that the sorting Benes network receives an input integer array n₀, n₁, . . . , n_{S-1}(0≦nᵢ<S and nᵢ≠nⱼ, if i≠j), and outputs switch control matrix C=BNSA(S; n₀, n₁, . . . , n_{S-1}), which can be represented as follows:

$$C = [ \begin{matrix}{C}_{0 , 0} & {C}_{0 , 1} & ⋯ & {C}_{0 , T - 1} \\ ⋮ & ⋮ & & ⋮ \\ {C}_{S / 2 - 1 , 0} & {C}_{S / 2 - 1 , 1} & ⋯ & {C}_{S / 2 - 1 , T - 1}\end{matrix} ]$$

where C_{m,n} represents a control state for switch 154 m of stage 152 n of each of the S/2×S/2 Benes networks 158a, 158b of the permuter 128, and T=2 log₂ (S)−1. The BNS algorithm, then, can operate on the input array in three stages (i.e., a first stage, middle stage and final stage) to calculate the output switch control matrix C. Notationally, the three stages can be written as follows:

```
First Stage:
    If n₀ is even, then e = 0, else e = 1
    For i = 0, . . . , S/2 − 1:
        If mod(n₂ᵢ, 2) = e and mod(n_{2i + 1}, 2) = 1 − e, then
            switch n₂ᵢ and n_{2i + 1}
            C_{i,0} = 1,
        else C_{i,0} = 0
    Shuffle (0, n₀, . . . , n_{S - 1})
Middle Stage - Iteration:
    If S > 4, then
        For i = 0, . . . , S − 1: ñᵢ = nᵢ >> 1
        C_{[0:S/4 - 1][1:T - 2]} = BNSA (S/2, ñ₀ , . . . , ñ_{S/2-1} )
        C_{[S/4:S/2 - 1][1:T - 2]} = BNSA (S/2, ñ_{S/2} , . . . , ñ_{S-1} )
        For j = 1, . . . , T − 2:
            For i = 0, . . . , S/2 − 1:
                If Cᵢⱼ > 0, then switch n₂ᵢ and n_{2i + 1}
            shuffle (j, n₀, . . . , n_{S - 1})
    else
        For i = 0, . . . , S/2 − 1:
            If n₂ᵢ > n_{2i + 1}, then switch n₂ᵢ and n_{2i + 1}
            C_{i,T - 2} = 1, else C_{i,T - 2} = 0
        shuffle (T − 2, n₀, . . . , n_{S - 1})
Last Stage:
    For i = 0, . . . , S/2 − 1:
        If n₂ᵢ > n_{2i + 1}, then
            switch n₂ᵢ and n_{2i + 1}
            C_{i,T - 1} = 1,
        else C_{i,T - 1} = 0
```

In the preceding BNS algorithm, nᵢ>>1 refers to a bit right-shift-by-one operation (i.e., removing the last bit from the binary representation of number nᵢ), and C_{[m1:m2][n1:n2]}refers to the following matrix:

$${C}_{[ m 1 \text{:} m 2 ] [ n 1 \text{:} n 2 ]} = [ \begin{matrix}{C}_{m 1 , n 1} & ⋯ & {C}_{m 1 , n 2} \\ ⋮ & & ⋮ \\ {C}_{m 2 , n 1} & ⋯ & {C}_{m 2 , n 2}\end{matrix} ]$$

Also, shuffle(j, n₀, . . . , n_{S-1}) refers to hard-wire interconnections between adjacent switch stages 152 j and j+1, which can be predetermined in the Benes network.

In various instances, the last stage of the BNS algorithm can be further simplified by determining the control C_{i,T-1} of the switch 152 by the parity of the last bit of n₂ᵢ, instead of comparing n₂ᵢ and n₂ᵢ₊₁. In such instances, if the last bit n₂ᵢ has parity one, the control C_{i,T-1} can also comprise one, thereby resulting in the two inputs to the respective switch being exchanged. Otherwise, the switch can pass the two inputs to respective outputs. Such a simplification, then, can further reduce the hardware resources required to implement the BNS algorithm.

As suggested above, the permuter 128 (and de-permuter 130) of exemplary embodiments of the present invention can support any cyclic shift S₀ smaller than S. For example, consider calculating a cyclic shift of a five-bit input array (i.e., S₀=5) with a shift offset of two (i.e., inputting array x₀, . . . , x₄, and outputting array x₂, . . . , x₄, x₀, x₁), the shift being calculated by a permuter including an 8-input Benes network (i.e., S=8). In such instances, the input and output positions can be predetermined and independent from the input array sizes and the shift offsets. The BNS algorithm, then, can be performed to calculate the input array shift, typically provided the input and output arrays are both positioned at the first S₀ pins of the Benes network, and provided the mapping of the integers follows the following rule:

$${n}_{i} = \{ \begin{matrix}mod ( i + {S}_{0 - s} , {S}_{0} ) , & i = 0 , 1 , … , {S}_{0} - 1 \\ i & i = {S}_{0} , … , S - 1\end{matrix}$$

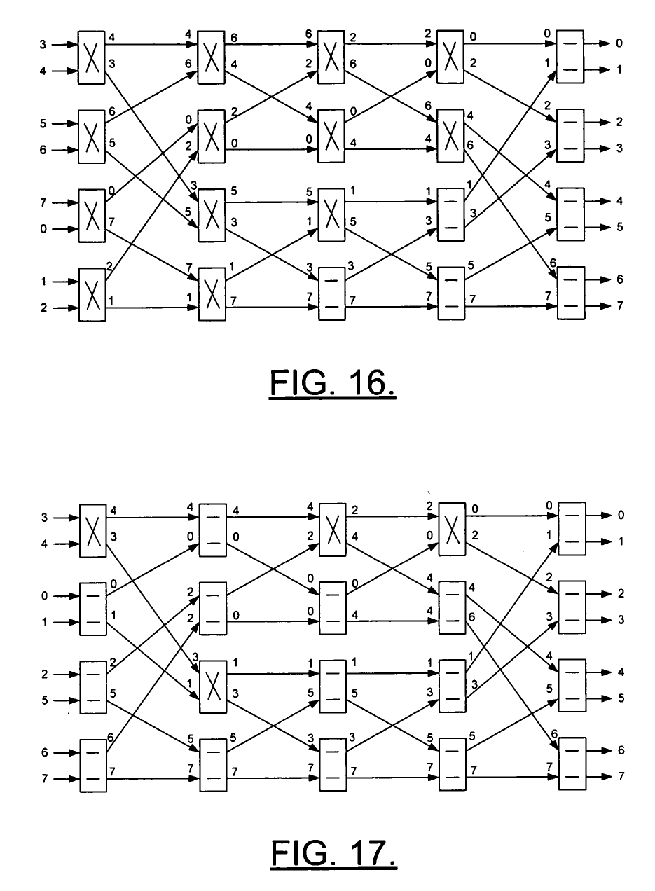

In FIGS. 16 and 17, two exemplary Benes networks are provided to illustrate how the BNS algorithm may sort input arrays of different sizes (i.e., different S₀) using the same Benes network. In the network of FIG. 16, S₀=S=8, and s=5. In FIG. 17, on the other hand, S₀=5, and s=2. For both of the illustrated input arrays, the network outputs the same values 0, 1, . . . , 7 in increasing sequence.

$$\begin{matrix}{c}_{i} {v}_{0}^{[ q ]} = {( - 1 )}^{8} {\prod }_{j {= 0 : 7}_{j \neq 0}} sign ( {v}_{j} {c}_{i}^{[ q - 1 ]} ) \times min ( \vert {v}_{1} {c}_{i}^{[ q - 1 ]} \vert , \vert {v}_{2} {c}_{i}^{[ q - 1 ]} \vert , … , \vert {v}_{7} {c}_{i}^{[ q - 1 ]} \vert ) \\ {c}_{i} {v}_{1}^{[ q ]} = {( - 1 )}^{8} {\prod }_{j {= 1 : 7}_{j \neq 1}} sign ( {v}_{j} {c}_{i}^{[ q - 1 ]} ) \times min ( \vert {v}_{0} {c}_{i}^{[ q - 1 ]} \vert , \vert {v}_{2} {c}_{i}^{[ q - 1 ]} \vert , … , \vert {v}_{7} {c}_{i}^{[ q - 1 ]} \vert ) \\ ⋮ \\ {c}_{i} {v}_{7}^{[ q ]} = {( - 1 )}^{8} {\prod }_{j {= 0 : 7}_{j \neq 7}} sign ( {v}_{j} {c}_{i}^{[ q - 1 ]} ) \times min ( \vert {v}_{1} {c}_{i}^{[ q - 1 ]} \vert , \vert {v}_{2} {c}_{i}^{[ q - 1 ]} \vert , … , \vert {v}_{6} {c}_{i}^{[ q - 1 ]} \vert )\end{matrix}$$

Now, assume that MIN and MIN2 are calculated at j=0 (i.e., I1=0) and j=1 (i.e., I2=7), respectively, as follows:
MIN=|v₀cₖ^{[q-1]}|=min(|v₀cᵢ^{[q-1]}|, |v₁cᵢ^{[q-1]}|, . . . , |v₇cᵢ^{[q-1]}|)
MIN2=|v₇cₖ^{[q-1]}|=min 2(|v₀cᵢ^{[q-1]}|, |v₁cᵢ^{[q-1]}|, . . . , |v₇cᵢ^{[q-1]}|)
The check-to-variable messages above can then be rewritten based upon MIN and MIN2 as follows:

$$\begin{matrix}{c}_{i} {v}_{0}^{[ q ]} = {( - 1 )}^{8} {S}_{i , 0} \times MIN 2 , & where {S}_{i , 0} = {\prod }_{j {= 0 : 7}_{j \neq 0}} sign ( {v}_{j} {c}_{i}^{[ q - 1 ]} ) \\ {c}_{i} {v}_{1}^{[ q ]} = {( - 1 )}^{8} {S}_{i , 1} \times MIN , & where {S}_{i , 1} = {\prod }_{j {= 0 : 7}_{j \neq 1}} sign ( {v}_{j} {c}_{i}^{[ q - 1 ]} ) \\ ⋮ & \\ {c}_{i} {v}_{7}^{[ q ]} = {( - 1 )}^{8} {S}_{i , 7} \times MIN , & where {S}_{i , 7} = {\prod }_{{j = 0 : 7}_{j \neq 7}} sign ( {v}_{j} {c}_{i}^{[ q - 1 ]} )\end{matrix}$$

Now, instead of storing cᵢv₀^{[q]}, cᵢv₁^{[q]}, . . . , cᵢv₇^{[q]}, the memory 106 can be configured to store MIN, MIN2, sign bits S_{i,0}, S_{i,1}, . . . , S_{i,7}, and index I1, where the sign of each message can be represented by a single bit.

For WiMAX applications, the maximum check node degree (number of non-zero sub-matrices in a layer) for a R-¾ code may be fifteen. Assuming 8-bit fixed-point precision, then, each check-node may require 15×8=120 bits of memory to store the associated check-to-variable messages. In exemplary embodiments of the present invention alternatively storing MIN, MIN2, sign bits and index I1, on the other

3. Memory Configuration

As explained above, the magnitude of the check-to-variable messages, M(cᵢvⱼ^{[q]}), can be approximated in accordance with a min-sum algorithm, such as in accordance with the following:
M(cᵢvⱼ^{[q]})≈min(|v_{j′}cᵢ^{[q-1]}|, j′=1, 2, . . . , ρⱼ−1, j′≠j)
where v_{j′}cᵢ^{[q-1]}=L(x_{j′})^{[q-1]}−cᵢv_{j′}^{[q-1]}. From the preceding, then, it can be shown that the magnitude M(cᵢvⱼ^{[q]}) can comprise MIN or MIN2. Thus, although the memory 106 of various exemplary embodiments of the present invention can store the check-to-variable messages cᵢvⱼ^{[q]}, the memory 106 of other exemplary embodiments alternatively store MIN and MIN2, along with a sign values

$${\prod }_{{j}^{′} ∈ R [ i ] \backslash \{ j \}} sign ( {v}_{{j}^{′}} {c}_{i}^{[ q - 1 ]} ) ,$$

and index of minimum value I1. The check-to-variable messages, then, can be calculated from the stored minimum, next minimum, sign and index values.

To illustrate the memory savings of such a memory configuration, consider an exemplary LDPC code with check-node degree of eight. Further, consider a check-node connected to variable nodes [0, 1, 2, . . . , 7] such that R[i]={0, 1, 2, 3, . . . , 7}. In such an instance, the eight variable-to-check messages and check-to-variable messages can be described as follows:

variable-to-check messages: v₀cᵢ^{[q-1]}, v₁cᵢ^{[q-1]}, . . . , v₇cᵢ^{[q-1]}

check-to-variable messages: cᵢv₀^{[q]}, cᵢv₁^{[q]}, . . . , cᵢv₇^{[q]}

In accordance with the min-sum algorithm, then, the check-to-variable messages can be calculated as follows: hand, 33 bits of memory may be required. In such instances, the number of bits can be calculated as the sum of 7 bits for each of MIN and MIN2, 1 sign bit for each of fifteen check-to-variable messages, and 4 bits (ceil(log₂ 15)) for index I1. Also in such instances, storing MIN, MIN2, sign bits and index I1 instead of the check-to-variable messages can reduce the required memory by roughly 70% or more. In addition, configuring the memory in this manner may reduce the number of latches required to delay check-to-variable messages in the pipelined decoder architecture.

In various instances, as explained above, the decoder architecture may implement a modified min-sum algorithm that accounts for an approximation error in the min-sum algorithm. In such instances, the modified min-sum algorithm also includes calculation of the third minimum value, and may also include storage of I2 and MIN3. Thus, in accordance with the modified min-sum algorithm, the amount of storage that may be required to accommodate a check-node for R-¾ WiMAX code with a check-node degree of fifteen can be calculated as the previous 33 bits plus an additional 8 bits (7-bit magnitude MIN3 and 4-bit value for the index of MIN3), for a total of 44 bits. Thus, in either instance of implementing the min-sum algorithm or modified min-sum algorithm, the number of bits required to store the magnitude and sign values, and the indices of the check-to-variable messages for those values, can be significantly lower than that required to store the check-to-variable messages themselves.

According to one exemplary aspect of the present invention, the functions performed by one or more of the entities of the system, such as the terminal 32, BS 34 and/or BSC 36 including respective transmitting and receiving entities 70, 72, may be performed by various means, such as hardware and/or firmware, including those described above, alone and/or under control of one or more computer program products. The computer program product(s) for performing one or more functions of exemplary embodiments of the present invention includes at least one computer-readable storage medium, such as the non-volatile storage medium, and software including computer-readable program code portions, such as a series of computer instructions, embodied in the computer-readable storage medium.

In this regard, FIGS. 5, 6, 9 and 10 are functional block and control flow diagrams illustrating methods, systems and program products according to exemplary embodiments of the present invention. It will be understood that each block or step of the functional block and control flow diagrams, and combinations of blocks in the functional block and control flow diagrams, can be implemented by various means, such as hardware, firmware, and/or software including one or more computer program instructions. These computer program instructions may be loaded onto a computer or other programmable apparatus to produce a machine, such that the instructions which execute on the computer or other programmable apparatus create means for implementing the functions specified in the functional block and control flow diagrams block(s) or step(s). As will be appreciated, any such computer program instructions may also be stored in a computer-readable memory that can direct a computer or other programmable apparatus (i.e., hardware) to function in a particular manner, such that the instructions stored in the computer-readable memory produce an article of manufacture including instruction means which implement the function specified in the functional block and control flow diagrams block(s) or step(s). The computer program instructions may also be loaded onto a computer or other programmable apparatus to cause a series of operational steps to be performed on the computer or other programmable apparatus to produce a computer implemented process such that the instructions which execute on the computer or other programmable apparatus provide steps for implementing the functions specified in the functional block and control flow diagrams block(s) or step(s).

Accordingly, blocks or steps of the functional block and control flow diagrams support combinations of means for performing the specified functions, combinations of steps for performing the specified functions and program instruction means for performing the specified functions. It will also be understood that one or more blocks or steps of the functional block and control flow diagrams, and combinations of blocks or steps in the functional block and control flow diagrams, can be implemented by special purpose hardware-based computer systems which perform the specified functions or steps, or combinations of special purpose hardware and computer instructions.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. An error correction decoder for block serial pipelined layered decoding of block codes, the error correction decoder comprising:
a plurality of elements capable of processing, for at least one of a plurality of iterations of an iterative decoding technique, at least one layer of a parity-check matrix, the plurality of elements including:
an iterative decoder element capable of calculating, for at least one iteration or at least one layer of the parity-check matrix processed during at least one iteration, a check-to-variable message based upon a first minimum magnitude and a second minimum magnitude of a plurality of variable-to-check messages for a previous iteration or layer, and a sign value associated with a plurality of variable-to-check messages for the previous iteration or layer, the first and second minimum magnitudes and sign value being read from a check-to-variable message memory.

2. An error correction decoder according to claim 1, wherein the parity-check matrix includes a plurality of columns corresponding to a plurality of variable nodes, wherein the plurality of variable-to-check messages have indices corresponding to respective variable nodes, the indices including a first index corresponding to the variable-to-check message having the first minimum magnitude, and
wherein the iterative decoder element is capable of calculating the check-to-variable message further based upon the first index.

3. An error correction decoder according to claim 2, wherein the iterative decoder element is capable of selecting one of the first or second minimum values, and selecting a sign value from a plurality of sign values associated with the plurality of variable-to-check messages for the previous iteration or layer, based upon the first index,
wherein the plurality of elements further include a read interface capable of reading the selected magnitude and sign value from the check-to-variable message memory, and
wherein the iterative decoder element is capable of calculating the check-to-variable message based upon the read magnitude and sign value.

4. An error correction decoder according to claim 1 further comprising:
a primary log-likelihood ratio (LLR) memory and a secondary LLR memory each capable of storing LLRs for at least one of the iterations of the iterative decoding technique,
wherein the iterative decoder element is further capable of calculating, for at least one iteration or at least one layer, a LLR adjustment based upon the LLR for a previous iteration or layer and the check-to-variable message for the previous iteration or layer, the LLR for the previous iteration or layer being read from the primary LLR memory, and
wherein the plurality of elements further include a summation element capable of calculating, for at least one iteration or at least one layer, the LLR based upon the LLR adjustment for the iteration or layer and the LLR for the previous iteration or layer, the LLR for the previous iteration or layer being read from the mirror LLR memory.

5. An error correction decoder according to claim 4, wherein the iterative decoder element is capable of calculating the check-to-variable message further based upon a third minimum magnitude of the plurality of variable-to-check messages for a previous iteration or layer, the third minimum magnitude also being read from the check-to-variable message memory.

6. An error correction decoder according to claim 1, wherein the iterative decoder element is further capable of calculating, for at least one iteration or at least one layer, at least a portion of a log-likelihood ratio (LLR) based upon the LLR for a previous iteration or layer and the check-to-variable message for the previous iteration or layer, and
wherein the plurality of elements further include at least one of a permuter or de-permuter capable of at least one of permuting the LLR for the previous iteration or layer, or de-permuting the at least a portion of the LLR for the iteration or layer, wherein the at least one of the permuter or de-permuter comprises:
a permuting Benes network that includes a plurality of switches for at least one of permuting the LLR for the previous iteration or layer, or de-permuting the at least a portion of the LLR for the iteration or layer; and
a sorting Benes network capable of generating control logic for the switches of the permuting Benes network.

7. An error correction decoder according to claim 6 further comprising:
a primary log-likelihood ratio (LLR) memory and a secondary LLR memory each capable of storing LLRs for at least one of a plurality of iterations of an iterative decoding technique,
wherein the at least a portion of the LLR calculated by the iterative decoder element comprises a LLR adjustment calculated based upon the LLR for a previous iteration or layer and the check-to-variable message for the previous iteration or layer, the LLR for the previous iteration or layer being read from the primary LLR memory, and
wherein the plurality of elements further include a summation element capable of calculating, for at least one iteration or at least one layer, the LLR based upon the LLR adjustment for the iteration or layer and the LLR for the previous iteration or layer, the LLR for the previous iteration or layer being read from the mirror LLR memory.

8. A method for block serial pipelined layered decoding of block codes, the method comprising processing, for at least one of a plurality of iterations of an iterative decoding technique, at least one layer of a parity-check matrix, the processing step including:
calculating, for at least one iteration or at least one layer of the parity-check matrix processed during at least one iteration, a check-to-variable message based upon a first minimum magnitude and a second minimum magnitude of a plurality of variable-to-check messages for a previous iteration or layer, and a sign value associated with a plurality of variable-to-check messages for the previous iteration or layer, the first and second minimum magnitudes and sign value being read from memory.

9. A method according to claim 8, wherein the parity-check matrix includes a plurality of columns corresponding to a plurality of variable nodes, wherein the plurality of variable-to-check messages have indices corresponding to respective variable nodes, the indices including a first index corresponding to the variable-to-check message having the first minimum magnitude, and
wherein the calculating step comprises calculating the check-to-variable message further based upon the first index.

10. A method according to claim 9, wherein the calculating step comprises:
selecting one of the first or second minimum values, and selecting a sign value from a plurality of sign values associated with the plurality of variable-to-check messages for the previous iteration or layer, based upon the first index;
reading the selected magnitude and sign value from memory; and
calculating the check-to-variable message based upon the read magnitude and sign value.

11. A method according to claim 8 further comprising:
storing, in a primary memory, log-likelihood ratios (LLRs) for at least one of the iterations of the iterative decoding technique;
storing, in a mirror memory, LLRs for at least one of the iterations of the iterative decoding technique,
wherein the processing step further includes:
calculating, for at least one iteration or at least one layer, a LLR adjustment based upon the LLR for a previous iteration or layer and the check-to-variable message for the previous iteration or layer, the LLR for the previous iteration or layer being read from the primary memory; and
calculating, for at least one iteration or at least one layer, the LLR based upon the LLR adjustment for the iteration or layer and the LLR for the previous iteration or layer, the LLR for the previous iteration or layer being read from the mirror memory.

12. A method according to claim 11, wherein the calculating a check-to-variable message step comprises calculating the check-to-variable message further based upon a third minimum magnitude of the plurality of variable-to-check messages for a previous iteration or layer, the third minimum magnitude also being read from memory.

13. A method according to claim 8, wherein the processing step further includes:
calculating, for at least one iteration or at least one layer, at least a portion of a log-likelihood ratio (LLR) based upon the LLR for a previous iteration or layer and the check-to-variable message for the previous iteration or layer; and
at least one of permuting the LLR for the previous iteration or layer, or de-permuting the at least a portion of the LLR for the iteration or layer, wherein the at least one of permuting or de-permuting step is performed at a permuting Benes network that includes a plurality of switches, and wherein the at least one of permuting or de-permuting step includes generating control logic for the switches of the permuting Benes network, the generating step being performed at a sorting Benes network.

14. A method according to claim 13 further comprising:
storing, in a primary memory, LLRs for at least one of a plurality of iterations of an iterative decoding technique;
storing, in a mirror memory, LLRs for at least one of the iterations of the iterative decoding technique,
wherein the calculating at least a portion of a LLR comprises calculating, for at least one iteration or at least one layer, a LLR adjustment based upon the LLR for a previous iteration or layer and the check-to-variable message for the previous iteration or layer, the LLR for the previous iteration or layer being read from the primary memory; and
calculating, for at least one iteration or at least one layer, the LLR based upon the LLR adjustment for the iteration or layer and the LLR for the previous iteration or layer, the LLR for the previous iteration or layer being read from the mirror memory.

15. A computer program product for block serial pipelined layered decoding of block codes, the computer program product comprising at least one computer-readable storage medium having computer-readable program code portions stored therein, the computer-readable program code portions comprising:
a first executable portion for processing, for at least some of a plurality of iterations of an iterative decoding technique, at least one layer of a parity-check matrix, wherein the first executable portion is adapted to process at least one layer for at least some of the iterations by calculating, for at least one iteration or at least one layer of the parity-check matrix processed during at least one iteration, a check-to-variable message based upon a first minimum magnitude and a second minimum magnitude of a plurality of variable-to-check messages for a previous iteration or layer, and a sign value associated with a plurality of variable-to-check messages for the previous iteration or layer, the first and second minimum magnitudes and sign value being read from a check-to-variable message memory.

16. A computer program product according to claim 15, wherein the parity-check matrix includes a plurality of columns corresponding to a plurality of variable nodes, wherein the plurality of variable-to-check messages have indices corresponding to respective variable nodes, the indices including a first index corresponding to the variable-to-check message having the first minimum magnitude, and
wherein the first executable portion is adapted to calculate the check-to-variable message further based upon the first index.

17. A computer program product according to claim 16, wherein the first executable portion is adapted to calculate the check-to-variable message by:
selecting one of the first or second minimum values, and selecting a sign value from a plurality of sign values associated with the plurality of variable-to-check messages for the previous iteration or layer, based upon the first index;
reading the selected magnitude and sign value from the check-to-variable message memory; and
calculating the check-to-variable message based upon the read magnitude and sign value.

18. A computer program product according to claim 15 further comprising:
a second executable portion for storing, in a primary log-likelihood ratio (LLR) memory, LLRs for at least one of a plurality of iterations of an iterative decoding technique;
a third executable portion for storing, in a mirror LLR memory, LLRs for at least one of the iterations of the iterative decoding technique,
wherein the first executable portion processing at least one layer for at least some of the iterations further includes:
calculating, for at least one iteration or at least one layer, a LLR adjustment based upon the LLR for a previous iteration or layer and the check-to-variable message for the previous iteration or layer, the LLR for the previous iteration or layer being read from the primary LLR memory; and
calculating, for at least one iteration or at least one layer, the LLR based upon the LLR adjustment for the iteration or layer and the LLR for the previous iteration or layer, the LLR for the previous iteration or layer being read from the mirror LLR memory.

19. A computer program product according to claim 18, wherein the first executable portion is adapted to calculate the check-to-variable message further based upon a third minimum magnitude of the plurality of variable-to-check messages for a previous iteration or layer, the third minimum magnitude also being read from the check-to-variable message memory.

20. A computer program product according to claim 15 wherein the first executable portion processing at least one layer for at least some of the iterations further includes:
calculating, for at least one iteration or at least one layer, at least a portion of a log-likelihood ratio (LLR) based upon the LLR for a previous iteration or layer and the check-to-variable message for the previous iteration or layer; and
at least one of permuting the LLR for the previous iteration or layer, or de-permuting the at least a portion of the LLR for the iteration or layer, wherein the first executable portion is adapted to implement a permuting Benes network that includes a plurality of switches for performing the permuting or de-permuting, and wherein the first executable portion is adapted to implement a sorting Benes network for generating control logic for the switches of the permuting Benes network.

21. A computer program product according to claim 20 further comprising:
a second executable portion for storing, in a primary LLR memory, LLRs for at least one of a plurality of iterations of an iterative decoding technique;
a third executable portion for storing, in a mirror LLR memory, LLRs for at least one of the iterations of the iterative decoding technique,
wherein the at least a portion of a LLR calculated by the first executable portion comprises a LLR adjustment calculated based upon the LLR for a previous iteration or layer and the check-to-variable message for the previous iteration or layer, the LLR for the previous iteration or layer being read from the primary LLR memory, and
wherein the first executable portion processing at least one layer for at least some of the iterations further includes calculating, for at least one iteration or at least one layer, the LLR based upon the LLR adjustment for the iteration or layer and the LLR for the previous iteration or layer, the LLR for the previous iteration or layer being read from the mirror LLR memory.
